(19) United States
(12) Patent Application Publication
(10) Pub. No.: US 2024/0387625 A1
(43) Pub. Date: Nov. 21, 2024

(54) SEMICONDUCTOR DEVICE AND METHODS OF FORMATION

(71) Applicant: Taiwan Semiconductor Manufacturing Company, Ltd., Hsinchu (TW)

(72) Inventor: Shahaji B. MORE, Hsinchu City (TW)

(21) Appl. No.: 18/785,024

(22) Filed: Jul. 26, 2024

Related U.S. Application Data
(62) Division of application No. 17/650,312, filed on Feb. 8, 2022.

(51) Int. Cl. H01L 29/06; H01L 21/8234; H01L 29/423; H01L 29/66; H01L 29/786

(52) U.S. Cl. CPC H01L 29/0665; H01L 21/823412; H01L 21/823418; H01L 29/42392; H01L 29/66553; H01L 29/66742; H01L 29/78618; H01L 29/78696

(57) ABSTRACT

An inner spacer is formed to a length that reduces the likelihood of non-growth in an epitaxial layer of a source/drain region of a nanostructure transistor. This reduces the likelihood that portion of the epitaxial layer become non-merged, which in turn reduces the likelihood of void formation in the source/drain region. Moreover, the epitaxial layer may be formed using a cyclic deposition and etch technique, which enables conformal growth of the epitaxial layer to further reduce the likelihood of void formation and to reduce the likelihood of nodule formation in the source/drain region. The reduction in defects may decrease semiconductor device failure, increase semiconductor device yield, and/or increase semiconductor device performance, among other examples.

### RELATED APPLICATION

This application is a divisional of U.S. patent application Ser. No. 17/650,312, filed Feb. 8, 2022, and entitled “SEMICONDUCTOR DEVICE AND METHODS OF FORMATION,” which is incorporated herein by reference in its entirety.

### BACKGROUND

As semiconductor device manufacturing advances and technology processing nodes decrease in size, transistors may become affected by short channel effects (SCEs) such as hot carrier degradation, barrier lowering, and quantum confinement, among other examples. In addition, as the gate length of a transistor is reduced for smaller technology nodes, source/drain (S/D) electron tunneling increases, which increases the off current for a transistor (the current that flows through the channel of the transistor when the transistor is in an off configuration). Silicon (Si)/silicon germanium (SiGe) nanostructure transistors such as nanowires, nanosheets, and gate-all-around (GAA) devices are potential candidates to overcome short channel effects at smaller technology nodes. Nanostructure transistors are efficient structures that may experience reduced SCEs and enhanced carrier mobility relative to other types of transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of a portion of an example semiconductor device described herein.

FIGS. 3A-3N, 4A-4D, and 5A-5E are diagrams of example implementations described herein.

FIG. 6 is a diagram of a portion of an example semiconductor device described herein.

FIGS. 7A-7G are diagrams of example implementations described herein.

FIG. 8 is a diagram of example components of one or more devices of FIG. 1 described herein.

FIGS. 9 and 10 are flowcharts of example processes associated with forming a semiconductor device.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Nanostructure transistors may be implemented, for example, in cases where fin field effect transistors (finFETs) cannot meet performance parameters for a semiconductor device. However, nanostructure transistor fabrication may be challenging and complex, particularly as device sizes and processing node sizes continue to decrease. For example, defects in a nanostructure transistor process flow can occur during formation of source/drain (S/D) region. The defects resulting from a non-merged epitaxial layer (e.g., an epitaxially layer in which non-growth in one or more areas of a source/drain region is experienced). Moreover, the defects may include nodules that are formed in the source/drain region, which can cause bridging during formation of the source/drain region. The defects may result in increased semiconductor device failures, reduced semiconductor device yield, and/or reduced semiconductor device performance, among other examples.

Some implementations described herein provide techniques and semiconductor devices in which inner spacers (InSPs) and source/drain regions are formed in a manner that provides reduced likelihood of defect formation in a nanostructure transistor. In some implementations, an inner spacer is formed to a length that reduces the likelihood of non-growth in an epitaxial layer of a source/drain region of a nanostructure transistor. This reduces the likelihood that portions of the epitaxial layer become non-merged, which in turn reduces the likelihood of void formation in the source/drain region. Moreover, the epitaxial layer may be formed using a cyclic deposition and etch technique, which enables conformal growth of the epitaxial layer to further reduce the likelihood of void formation and to reduce the likelihood of nodule formation in the source/drain region. The reduction in defects may decrease semiconductor device failure, increase semiconductor device yield, and/or increase semiconductor device performance, among other examples.

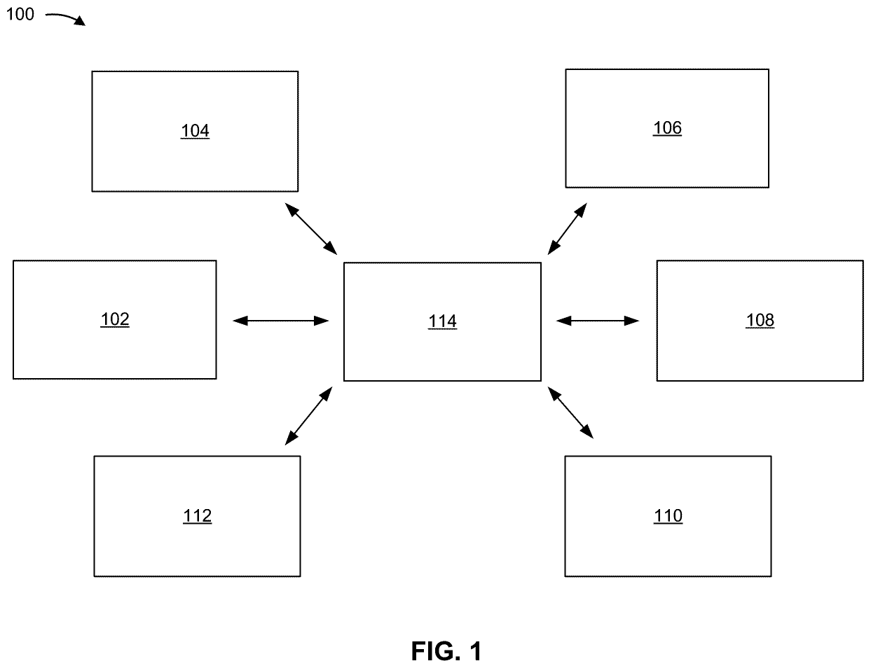

FIG. 1 is a diagram of an example environment 100 in which systems and/or methods described herein may be implemented. As shown in FIG. 1, environment 100 may include a plurality of semiconductor processing tools 102-112 and a wafer/die transport tool 114. The plurality of semiconductor processing tools 102-112 may include a deposition tool 102, an exposure tool 104, a developer tool 106, an etch tool 108, a planarization tool 110, a plating tool 112, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

Wafer/die transport tool 114 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-112, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 114 may be a programmed device that is configured to travel a particular path and/or may operate semi-autonomously or autonomously. In some implementations, the environment 100 includes a plurality of wafer/die transport tools 114.

For example, the wafer/die transport tool 114 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 114 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 114 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of environment 100 may perform one or more functions described as being performed by another set of devices of environment 100.

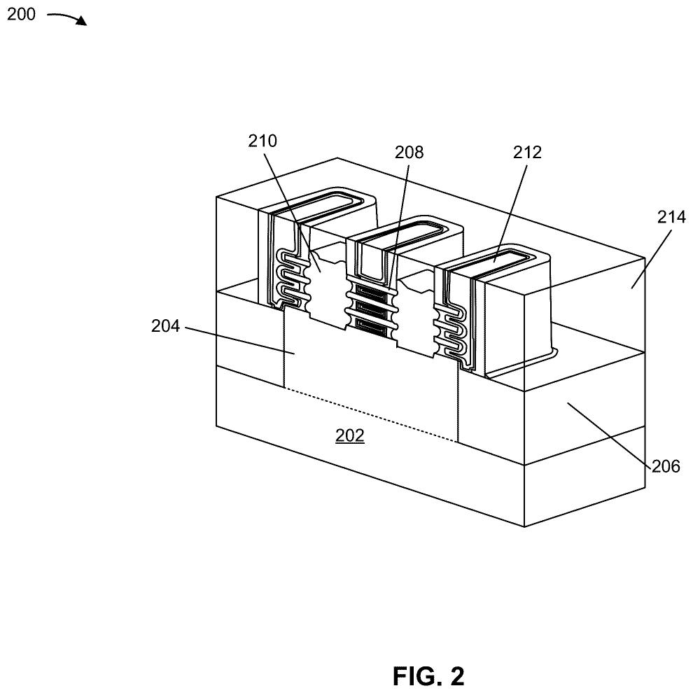

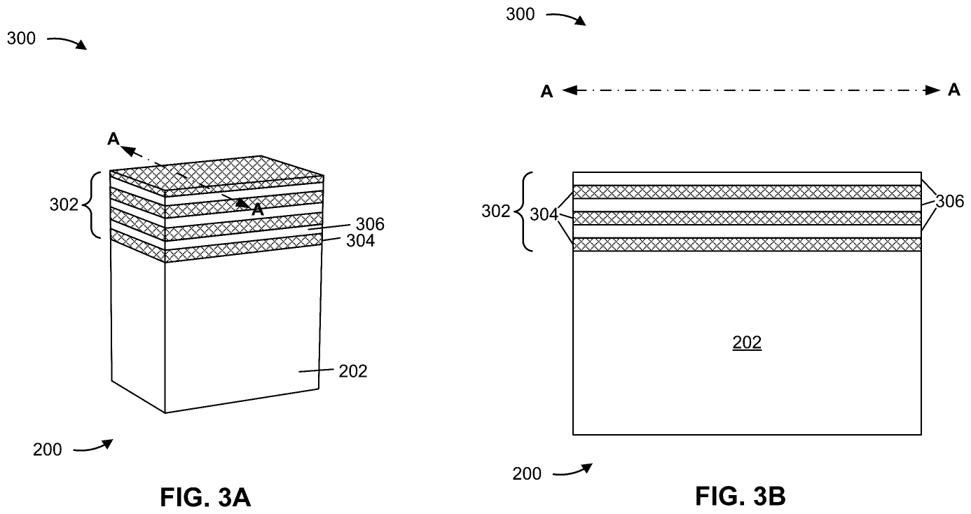

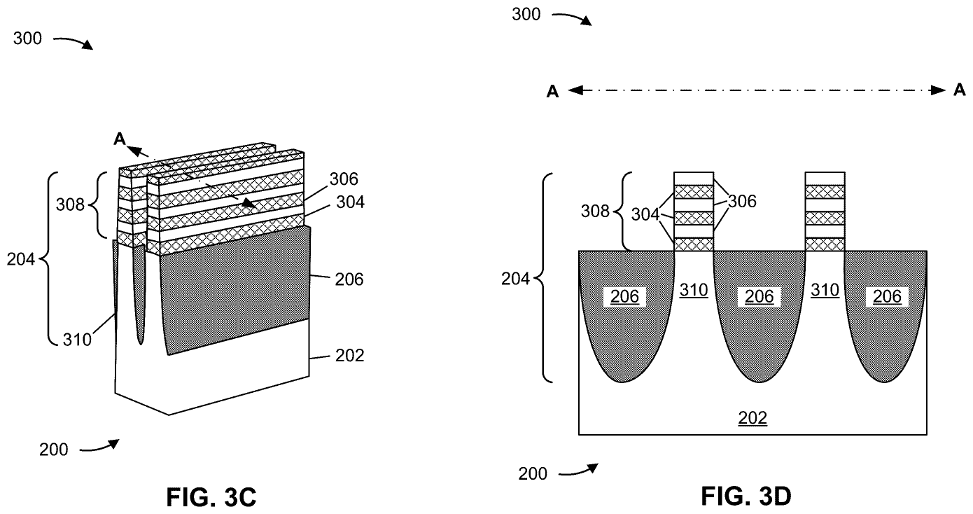

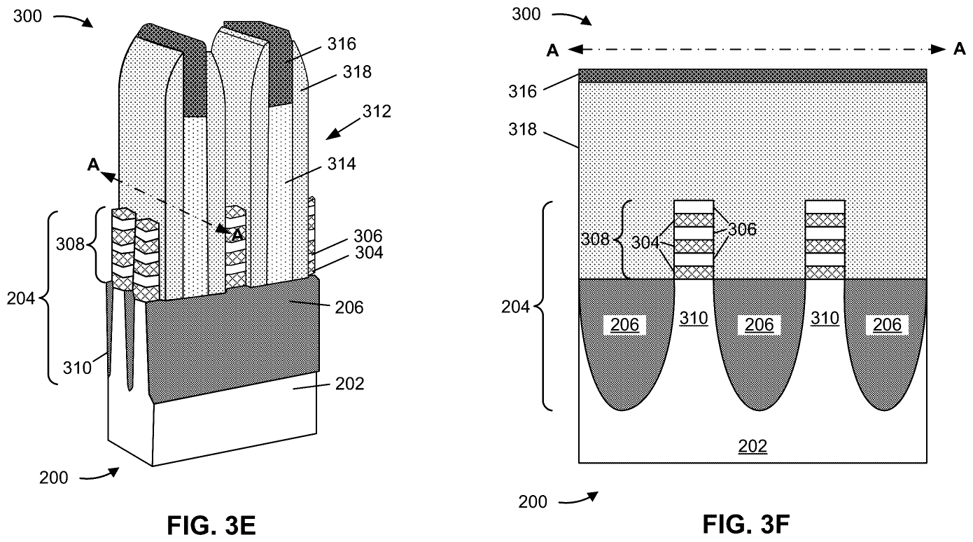

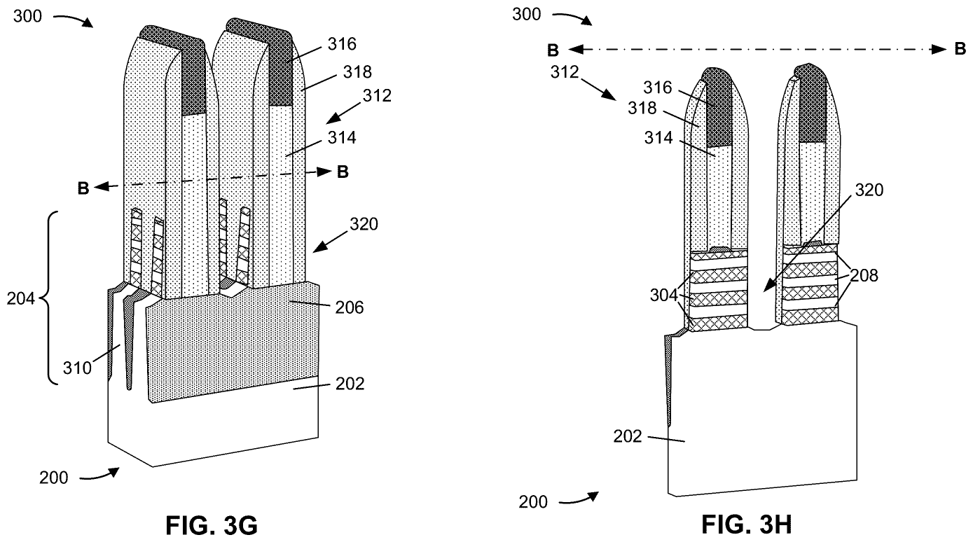

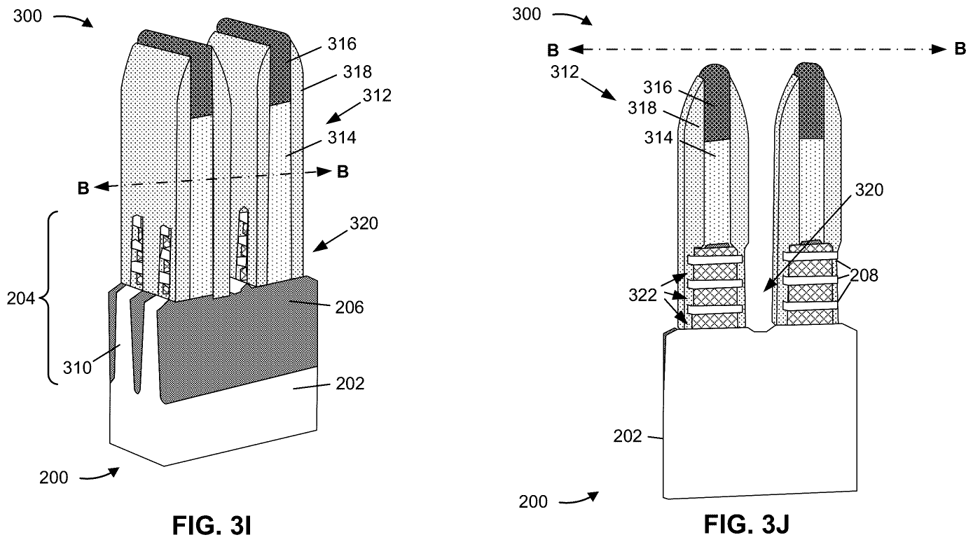

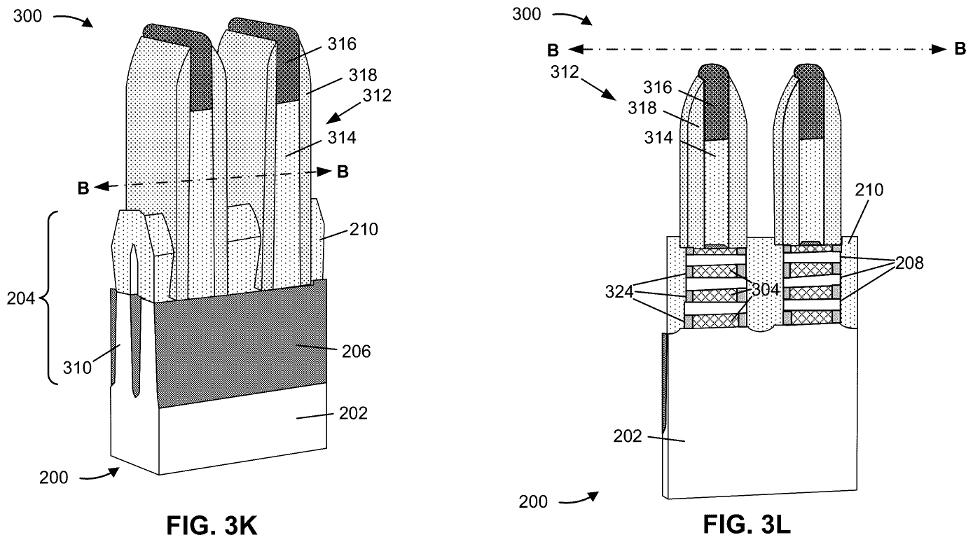

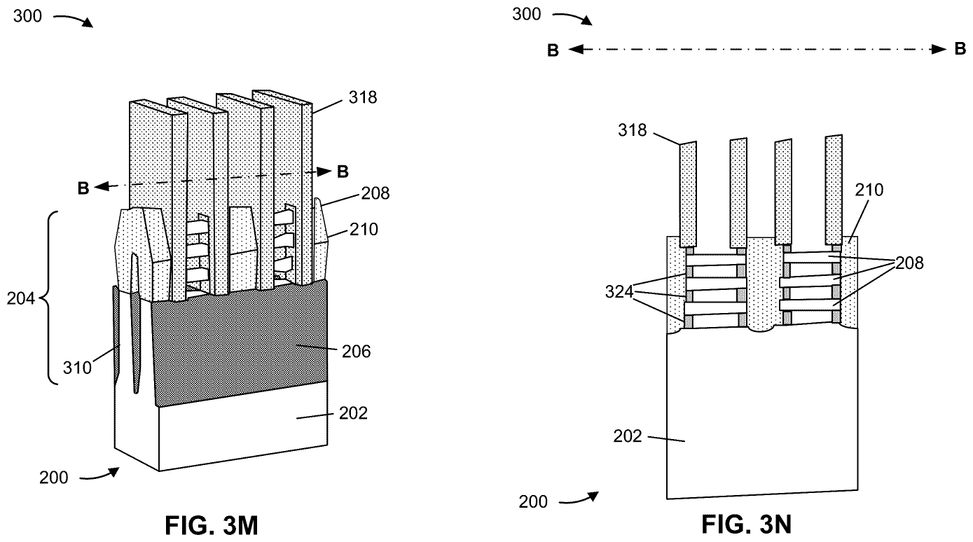

FIG. 2 is a diagram of an example semiconductor device 200 described herein. The semiconductor device 200 includes one or more transistors. The one or more transistors may include nanostructure transistor(s) such as nanowire transistors, nanosheet transistors, gate-all-around (GAA) transistors, multi-bridge channel transistors, nanoribbon transistors, and/or other types of nanostructure transistors. The semiconductor device 200 may include one or more additional devices, structures, and/or layers not shown in FIG. 2. For example, the semiconductor device 200 may include additional layers and/or dies formed on layers above and/or below the portion of the semiconductor device 200 shown in FIG. 2. Additionally, or alternatively, one or more additional semiconductor structures and/or semiconductor devices may be formed in a same layer of an electronic device or integrated circuit (IC) that includes the semiconductor device, with a lateral displacement, as the semiconductor device 200 shown in FIG. 2. FIGS. 3A-3N, 4A-4D, 5A-5E, 6, and 7 are perspective and/or schematic cross-sectional views of various portions of the semiconductor device 200 illustrated in FIG. 2, and correspond to various processing stages of forming nano structure transistors of the semiconductor device 200.

The semiconductor device 200 includes a substrate 202. The substrate 202 includes a silicon (Si) substrate, a substrate formed of a material including silicon, a III-V compound semiconductor material substrate such as gallium arsenide (GaAs), a silicon on insulator (SOI) substrate, a germanium substrate (Ge), a silicon germanium (SiGe) substrate, a silicon carbide (SiC) substrate, or another type of semiconductor substrate. The substrate 202 may include various layers, including conductive or insulating layers formed on a semiconductor substrate. The substrate 202 may include a compound semiconductor and/or an alloy semiconductor. The substrate 202 may include various doping configurations to satisfy one or more design parameters. For example, different doping profiles (e.g., n-wells, p-wells) may be formed on the substrate 202 in regions designed for different device types (e.g., p-type metal-oxide semiconductor (PMOS) nanostructure transistors, n-type metal-oxide semiconductor (NMOS) nanostructure transistors). The suitable doping may include ion implantation of dopants and/or diffusion processes. Further, the substrate 202 may include an epitaxial layer (epi-layer), may be strained for performance enhancement, and/or may have other suitable enhancement features. The substrate 202 may include a portion of a semiconductor wafer on which other semiconductor devices are formed.

Fin structures 204 are included above (and/or extend above) the substrate 202. A fin structure 204 provide a structure on which layers and/or other structures of the semiconductor device 200 are formed, such as epitaxial regions and/or gate structures, among other examples. In some implementations, the fin structures 204 include the same material as the substrate 202 and are formed from the substrate 202. In some implementations, the fin structures 204 include silicon (Si) materials or another elementary semiconductor material such as germanium (Ge). In some implementations, the fin structures 204 include an alloy semiconductor material such as silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), gallium indium arsenide phosphide (GaInAsP), or a combination thereof.

The fin structures 204 are fabricated by suitable semiconductor process techniques, such as masking, photolithography, and/or etch processes, among other examples. As an example, the fin structures 204 may be formed by etching a portion of the substrate 202 away to form recesses in the substrate 202. The recesses may then be filled with isolating material that is recessed or etched back to form shallow trench isolation (STI) regions 206 above the substrate 202 and between the fin structures 204. Other fabrication techniques for the STI regions 206 and/or for the fin structures 204 may be used. The STI regions 206 may electrically isolate adjacent fin structures 204 and may provide a layer on which other layers and/or structures of the semiconductor device 200 are formed. The STI regions 206 may include a dielectric material such as a silicon oxide (SiOₓ), a silicon nitride (SiₓN_{y}), a silicon oxynitride (SiON), fluoride-doped silicate glass (FSG), a low-k dielectric material, and/or other suitable insulating material. The STI regions 206 may include a multi-layer structure, for example, having one or more liner layers.

The semiconductor device 200 includes a plurality of channels 208 that extend between, and are electrically coupled with, source/drain regions 210. The channels 208 include silicon-based nanostructures (e.g., nanosheets or nanowires, among other examples) that function as the semiconductive channels of the nanostructure transistor(s) of the semiconductor device 200. The channels 208 may include silicon germanium (SiGe) or another silicon-based material. The source/drain regions 210 include silicon (Si) with one or more dopants, such as a p-type material (e.g., boron (B) or germanium (Ge), among other examples), an n-type material (e.g., phosphorous (P) or arsenic (As), among other examples), and/or another type of dopant. Accordingly, the semiconductor device 200 may include p-type metal-oxide semiconductor (PMOS) nanostructure transistors that include p-type source/drain regions 210, n-type metal-oxide semiconductor (NMOS) nanostructure transistors that include n-type source/drain regions 210, and/or other types of nanostructure transistors.

At least a subset of the channels 208 extend through one or more gate structures 212. The gate structures 212 may be formed of one or more metal materials, one or more high dielectric constant (high-k) materials, and/or one or more other types of materials. In some implementations, dummy gate structures (e.g., polysilicon (PO) gate structures or another type of gate structures) are formed in the place of (e.g., prior to formation of) the gate structures 212 so that one or more other layers and/or structures of the semiconductor device 200 may be formed prior to formation of the gate structures 212. This reduces and/or prevents damage to the gate structures 212 that would otherwise be caused by the formation of the one or more layers and/or structures. A replacement gate process (RGP) is then performed to remove the dummy gate structures and replace the dummy gate structures with the gate structures 212 (e.g., replacement gate structures).

As further shown in FIG. 2, portions of a gate structure 212 are formed in between pairs of channels 208 in an alternating vertical arrangement. In other words, the semiconductor device 200 includes one or more vertical stacks of alternating channels 208 and portions of a gate structures 212, as shown in FIG. 2. In this way, a gate structure 212 wraps around an associated channel 208 on all sides of the channel 208 which increases control of the channel 208, increases drive current for the nanostructure transistor(s) of the semiconductor device 200, and reduces short channel effects (SCEs) for the nanostructure transistor(s) of the semiconductor device 200.

Some source/drain regions 210 and gate structures 212 may be shared between two or more nanoscale transistors of the semiconductor device 200. In these implementations, one or more source/drain regions 210 and a gate structure 212 may be connected or coupled to a plurality of channels 208, as shown in the example in FIG. 2. This enables the plurality of channels 208 to be controlled by a single gate structure 212 and a pair of source/drain regions 210.

The semiconductor device 200 may also include a dielectric layer 214 above the STI regions 206. The dielectric layer 214 may include an inter-layer dielectric (ILD) layer ad may be referred to as an ILDO layer. The dielectric layer 214 surrounds the gate structures 212 to provide electrical isolation and/or insulation between the gate structures 212 and/or the source/drain regions 210, among other examples. Conductive structures such as contacts and/or interconnects may be formed through the dielectric layer 214 to the source/drain regions 210 and the gate structures 212 to provide control of the source/drain regions 210 and the gate structures 212.

As indicated above, FIG. 2 is provided as an example. Other examples may differ from what is described with regard to FIG. 2.

FIGS. 3A-3N are diagrams of an example implementation 300 described herein. The example implementation 300 includes an example of forming the semiconductor device 200 or a portion thereof (e.g., an example of forming nanostructure transistor(s) of the semiconductor device 200). Operations shown in the example implementation 300 may be performed in a different order from the order shown in FIGS. 3A-3N. The semiconductor device 200 may include one or more additional devices, structures, and/or layers not shown in FIGS. 3A-3N. For example, the semiconductor device 200 may include additional layers and/or dies formed on layers above and/or below the portion of the semiconductor device 200 shown in FIGS. 3A-3N. Additionally, or alternatively, one or more additional semiconductor structures and/or semiconductor devices may be formed in a same layer of an electronic device that includes the semiconductor device 200.

FIGS. 3A and 3B respectively illustrate a perspective view of the semiconductor device 200 and a cross-sectional view along the line A-A in FIG. 3A. As shown in FIGS. 3A and 3B, processing of the semiconductor device 200 is performed in connection with the substrate 202. A layer stack 302 is formed on the substrate 202. The layer stack 302 may be referred to as a superlattice. In some implementations, one or more operations are performed in connection with the substrate 202 prior to formation of the layer stack 302. For example, an anti-punch through (APT) implant operation may be performed. The APT implant operation may be performed in one or more regions of the substrate 202 above which channels 208 are to be formed. The APT implant operation is performed, for example, to reduce and/or prevent punch-through or unwanted diffusion into the substrate 202.

The layer stack 302 includes a plurality of alternating layers. The alternating layers include a plurality of first layers 304 and a plurality of second layers 306. The quantity of first layers 304 and the quantity of second layers 306 illustrated in FIGS. 3A and 3B are examples, and other quantities of the first layers 304 and the second layers 306 are within the scope of the present disclosure. In some implementations, the first layers 304 and the second layers 306 are formed to different thicknesses. For example, the second layers 306 may be formed to a thickness that is greater relative to a thickness of the first layers 304. In some implementations, the first layers 304 (or a subset thereof) are formed to a thickness in a range of approximately 4 nanometers to approximately 7 nanometers. In some implementations, the second layers 306 (or a subset thereof) are formed to a thickness in a range of approximately 8 nanometers to approximately 12 nanometers. However, other values for the thickness of the first layers 304 and for the thickness of the second layers 306 are within the scope of the present disclosure.

The first layers 304 include a first material composition, and the second layers 306 include a second material composition. In some implementations, the first material composition and second material composition are the same material composition. In some implementations, the first material composition and second material composition are different material compositions. As an example, the first layers 304 may include silicon germanium (SiGe) and the second layers 306 may include silicon (Si). In some implementations, the first material composition and the second material composition have different oxidation rates and/or etch selectivity.

As described herein, the second layers 306 may be processed to form the channel 208 for subsequently-formed nanostructure transistors of the semiconductor device 200. The first layers 304 are eventually removed and serve to define a vertical distance between adjacent channel 208 for subsequently-formed nanostructure transistors of the semiconductor device 200. Accordingly, the first layers 304 may also be referred to as sacrificial layers, and second layers 306 may be referred to as channel layers.

The deposition tool 102 deposits and/or grows the alternating layers that include nanostructures (e.g., nanosheets) on the substrate 202. For example, the deposition tool 102 grows the alternating layers by epitaxial growth. However, other processes may be used to form the alternating layers of the layer stack 302. Epitaxial growth of the alternating layers of the layer stack 302 may be performed by a molecular beam epitaxy (MBE) process, a metalorganic chemical vapor deposition (MOCVD) process, and/or other suitable epitaxial growth processes. In some implementations, the epitaxially grown layers such as the second layers 306 include the same material as the material of the substrate 202. In some embodiments, the first layers 304 and/or the second layers 306 include a material that is different from the material of the substrate 202. As described above, in some implementations, the first layers 304 include epitaxially grown silicon germanium (SiGe) layers and the second layers 306 include epitaxially grown silicon (Si) layers. Alternatively, the first layers 304 and/or the second layers 306 may include other materials such as germanium (Ge), a compound semiconductor such as silicon carbide (SiC), gallium arsenide (GaAs), gallium phosphide (GaP), indium phosphide (InP), indium arsenide (InAs), indium antimonide (InSb), an alloy semiconductor such as silicon germanium (SiGe), gallium arsenide phosphide (GaAsP), aluminum indium arsenide (AlInAs), aluminum gallium arsenide (AlGaAs), indium gallium arsenide (InGaAs), gallium indium phosphide (GaInP), gallium indium arsenide phosphide (GaInAsP), and/or a combination thereof. The materials of the first layers 304 and/or the materials of the second layers 306 may be chosen based on providing different oxidation properties, different etching selectivity properties, and/or other different properties.

FIGS. 3C and 3D respectively illustrate a perspective view of the semiconductor device 200 and a cross-sectional view along the line A-A in FIG. 3C. As shown in FIGS. 3C and 3D, fin structures 204 are formed above the substrate 202 of the semiconductor device 200. A fin structure 204 includes a portion 308 of the layer stack 302 above and/or on a portion 310 formed in and/or above the substrate 202. The portion 310 may be referred to as a mesa region, a silicon mesa, or a pedestal of the fin structures 204, among other examples. The fin structures 204 may be formed by any suitable semiconductor processing technique. For example, the fin structures 204 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, a sacrificial layer may be formed over a substrate and patterned using a photolithography process. Spacers are formed alongside the patterned sacrificial layer using a self-aligned process. The sacrificial layer is then removed, and the remaining spacers may then be used to pattern the fin structures.

In some implementations, the deposition tool 102 forms a hard mask (HM) layer over the layer stack 302 prior to patterning the fin structures 204. In some implementations, the hard mask layer includes an oxide layer (e.g., a pad oxide layer that may include silicon dioxide (SiO₂) or another material) and a nitride layer (e.g., a pad nitride layer that may include a silicon nitride such as Si₃N₄ or another material) formed over the oxide layer. The oxide layer may function as an adhesion layer between the layer stack 302 and the nitride layer, and may act as an etch stop layer for etching the nitride layer. In some implementations, the hard mask layer includes a thermally grown oxide, a chemical vapor deposition (CVD)-deposited oxide, and/or an atomic layer deposition (ALD)-deposited oxide, among other examples. In some implementations, the hard mask layer includes a nitride layer deposited by CVD and/or another suitable technique.

The fin structures 204 may subsequently be fabricated using suitable processes including photolithography and etch processes. In some implementations, the deposition tool 102 forms a photoresist layer over and/or on the hard mask layer, the exposure tool 104 exposes the photoresist layer to radiation (e.g., deep ultraviolet (UV) radiation, extreme UV (EUV) radiation), a post-exposure bake process is performed (e.g., to remove residual solvents from the photoresist layer), and the developer tool 106 develops the photoresist layer to form a masking element (or pattern) in the photoresist layer. In some embodiments, patterning the photoresist layer to form the masking element may be performed using an electron beam (e-beam) lithography process. The masking element may then be used to protect portions of the substrate 202 and portions of the layer stack 302 in an etch operation such that the portions of the substrate 202 and portions of the layer stack 302 remain non-etched to form the fin structures 204. Unprotected portions of the substrate and unprotected portions of the layer stack 302 are etched (e.g., by the etch tool 108) to form trenches in the substrate 202. The etch tool may etch the unprotected portions of the substrate and unprotected portions of the layer stack 302 using a dry etch technique (e.g., reactive ion etching), a wet etch technique, and/or a combination thereof.

In some implementations, another fin formation technique is used to form the fin structures 204. For example, a fin region may be defined (e.g., by mask or isolation regions) and, and the portions 308 may be epitaxially grow in the form of the fin structure 204. In some embodiments, forming the fin structures 204 includes a trim process to decrease the width of the fin structures 204. The trim process may include wet and/or dry etching processes, among other examples.

As further shown in FIGS. 3C and 3D, STI regions 206 are formed above the substrate 202 and interposing (e.g., in between) the fin structures 204. The deposition tool 102 may deposit a dielectric layer over the substrate 202 and in the trenches between the fin structures 204. The deposition tool 102 may form the dielectric layer such that a height of a top surface of the dielectric layer and a height of a top surface of the hard mask layer are approximately a same height. Alternatively, the deposition tool 102 may form the dielectric layer such that the height of the top surface of the dielectric layer is greater relative to the height of the top surface of the hard mask layer. The deposition tool 102 may deposit the dielectric layer using a CVD technique, a PVD technique, an ALD technique, and/or another deposition technique. In some implementations, after deposition of the dielectric layer, the semiconductor device 200 is annealed, for example, to increase the quality of the dielectric layer.

The dielectric layer includes a dielectric material such as a silicon oxide (SiOₓ), a silicon nitride (SiₓN_{y}), a silicon oxynitride (SiON), fluoride-doped silicate glass (FSG), a low-k dielectric material, and/or other suitable insulating material. In some embodiments, the dielectric layer (and subsequently formed STI regions 206) may include a multi-layer structure, for example, having one or more liner layers.

After deposition of the dielectric layer, the planarization tool 110 performs a planarization or polishing operation (e.g., a CMP operation) to planarize the dielectric layer. The hard mask layer may function as a CMP stop layer in the operation. In other words, the planarization tool 110 planarizes the dielectric layer until reaching the hard mask layer. An etch back operation is then performed to remove portions of the dielectric layer to form the STI regions 206. The etch tool 108 may etch the dielectric layer in the etch back operation to form the STI regions 206. The etch tool 108 etches the dielectric layer based on the pattern in the hard mask layer. The etch tool 108 etches the dielectric layer such that the height of the STI regions 206 are less than or approximately a same height as the bottom of the portions 308 of the layer stack 302. Accordingly, the portions 306 of the layer stack 302 extend above the STI regions 206.

The hard mask layer may also be removed before, during, and/or after the etch back operation to form the STI regions 206. The hard mask layer may be removed, for example, by a wet etching process using phosphoric acid (H₃PO₄) or other suitable etchants. In some implementations, the hard mask layer is removed by the same etchant used to form the STI regions 206.

FIGS. 3E and 3F respectively illustrate a perspective view of the semiconductor device 200 and a cross-sectional view along the line A-A in FIG. 3E. As shown in FIGS. 3E and 3F, dummy gate structures 312 (also referred to as dummy gate stacks) are formed for the semiconductor device 200. As described above, the dummy gate structures 312 are sacrificial structures that are to be replaced by replacement gate structures (or replacement gate stacks) at a subsequent processing stage for the semiconductor device 200. In some implementations, the dummy gate structures 312 are formed over the substrate 202 and are at least partially formed over the fin structures 204. The dummy gate structures 312 extend above the portions 308 of the layer stack 302. Portions of the fin structures 204 underlying the dummy gate structures 312 may be referred to as channel regions. The dummy gate structures 312 may also define source/drain (S/D) regions of the fin structures 204, such as the regions of the fin structures 204 adjacent and on opposing sides of the channel regions.

A dummy gate structure 312 may include a gate electrode layer 314, a hard mask layer 316 over and/or on the gate electrode layer 314, and spacer layers 318 on opposing sides of the gate electrode layer 314 and on opposing sides of the hard mask layer 316. In some implementations, a dummy gate structure 312 includes additional layers such as a gate dielectric layer between the portions 308 of the layer stack 302 and the gate electrode layer 314. The gate electrode layer 314 includes polycrystalline silicon (polysilicon or PO) or another material. The hard mask layer 316 includes one or more layers such as an oxide layer (e.g., a pad oxide layer that may include silicon dioxide (SiO₂) or another material) and a nitride layer (e.g., a pad nitride layer that may include a silicon nitride such as Si₃N₄ or another material) formed over the oxide layer. The gate dielectric layer may include a silicon oxide (e.g., SiOₓ such as SiO₂), a silicon nitride (e.g., SiₓN_{y} such as Si₃N₄), a high-K dielectric material and/or other suitable material. The spacer layers 318 include a silicon oxycarbide (SiOC), a nitrogen free SiOC, or another suitable material. The gate dielectric layer may be included to prevent damage to the structures by subsequent processes (e.g., subsequent formation of the dummy gate structures 312).

The layers of the dummy gate structures 312 may be formed using various semiconductor processing techniques such as deposition (e.g., by the deposition tool 102), pattering (e.g., by the exposure tool 104 and the developer tool 106), and/or etching (e.g., by the etch tool 108), among other examples. Examples include CVD, PVD, ALD, thermal oxidation, c-beam evaporation, photolithography, e-beam lithography, photoresist coating (e.g., spin-on coating), soft baking, mask aligning, exposure, post-exposure baking, photoresist developing, rinsing, drying (e.g., spin-drying and/or hard baking), dry etching (e.g., reactive ion etching), and/or wet etching, among other examples.

In some implementations, the gate dielectric layer of the dummy gate structures 312 is conformally deposited on the semiconductor device 200 and then selectively removed from portions of the semiconductor device 200 (e.g., the source/drain areas). The gate electrode layer 314 is then deposited onto the remaining portions of the gate dielectric layer. The hard mask layers 316 are then deposited onto the gate electrode layers 314. The spacer layers 318 may be conformally deposited in a similar manner as the gate dielectric layer. In some implementations, the spacer layers 318 include a plurality of types of spacer layers. For example, the spacer layers 318 may include a seal spacer layer that is formed on the sidewalls of the dummy gate structures 312 and bulk spacer layer that is formed on the seal spacer layer. The seal spacer layer and the bulk spacer layer may be formed of similar materials or different materials. In some implementations, the bulk spacer layer is formed without plasma surface treatment that is used for the seal spacer layer. In some implementations, the bulk spacer layer is formed to a greater thickness relative to the thickness of the seal spacer layer.

FIGS. 3G and 3H respectively illustrate a perspective view of the semiconductor device 200 and a cross-sectional view along the line B-B in FIG. 3G. As shown in FIGS. 3G and 3H, source/drain recesses 320 are formed in the portions 308 of the fin structure 204 in an etch operation. The source/drain recesses 320 are formed to provide spaces in which source/drain regions 210 are to be formed on opposing sides of the dummy gate structures 312. The etch operation may be performed by the etch tool 108 and may be referred to a strained source/drain (SSD) etch operation. In some implementations, the etch operation includes a plasma etch technique, a wet chemical etch technique, and/or another type of etch technique.

As further shown in FIGS. 3G and 3H, the source/drain recesses 320 may further be formed into the portions 310 of the fin structure 204. In these implementations, the source/drain recesses 320 penetrate into a well portion (e.g., a p-well, an n-well) of the fin structure 204. In implementations in which the substrate 202 includes a silicon (Si) material having a (100) orientation, (111) faces are formed at bottoms of the source/drain recesses 320, resulting in formation of a V-shape or a triangular shape cross section at the bottoms of the source/drain recesses 320. In some embodiments, a wet etching using tetramethylammonium hydroxide (TMAH) and/or a chemical dry etching using hydrochloric acid (HCl) are employed to form the V-shape profile.

As further shown in FIGS. 3G and 3H, portions of the first layers 304 and portions of the second layers 306 of the layer stack 302 remain under the dummy gate structures 312 after the etch operation to form the source/drain recesses 320. The portions of the second layers 306 under the dummy gate structures 312 form the channels 208 of the nanostructure transistors of the semiconductor device 200.

FIGS. 3I and 3J respectively illustrate a perspective view of the semiconductor device 200 and a cross-sectional view along the line B-B in FIG. 3I. As shown in FIGS. 3I and 3J, the first layers 304 are laterally etched (e.g., in a direction that is approximately parallel to a length of the first layers 304) in an etch operation, thereby forming cavities 322 between portions of the channels 208. In implementations where the first layers 304 are silicon germanium (SiGe) and the second layers 306 are silicon (Si), the etch tool 108 may selectively etch the first layers 304 using a wet etchant such as, a mixed solution including hydrogen peroxide (H₂O₂), acetic acid (CH₃COOH), and/or hydrogen fluoride (HF), followed by cleaning with water (H₂O). The mixed solution and the wafer may be provided into the source/drain recesses 320 to etch the first layers 304 from the source/drain recesses 320. In some embodiments, the etching by the mixed solution and cleaning by water is repeated approximately 10 to approximately 20 times. The etching time by the mixed solution is in a range from about 1 minute to about 2 minutes in some implementations. The mixed solution may be used at a temperature in a range of approximately 60° Celsius to approximately 90° Celsius. However, other values for the parameters of the etch operation are within the scope of the present disclosure.

FIGS. 3K and 3L respectively illustrate a perspective view of the semiconductor device 200 and a cross-sectional view along the line B-B in FIG. 3K. As shown in FIGS. 3K and 3L, inner spacers (InSP) 324 are formed in the cavities 322 between the channels 208. The inner spacers 324 may be formed on ends of the first layers 304 through the source/drain recesses 320. The inner spacers 324 include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another dielectric material. As described herein, a layer of material may be conformally deposited in the source/drain recesses 320 and cavities 322, and the layer of material may be etched back to remove excess material to form the inner spacers 324. The inner spacers 324 provide physical isolation and/or electrical isolation between the source/drain regions 210 and the metal gate structures that are to replace the dummy gate structures 312. In this way, the inner spacers 324 may reduce short channel effects in the semiconductor device 200 and may reduce dopant leakage and/or diffusion from the source/drain regions 210 into the metal gate structures and/or into the mesa regions (e.g., the portions 310) of the fin structures 204, which increases the performance of the semiconductor device 200 and/or increases yield of semiconductor devices 200 formed on a wafer, among other examples.

As further shown in FIGS. 3K and 3L, source/drain regions 210 are formed in the source/drain recesses 320 on opposing sides of the dummy gate structures 312 after formation of the inner spacers 324. The deposition tool 102, the etch tool 108, and/or another semiconductor processing tool forms the source/drain regions 210 using one or more semiconductor processing techniques, such as epitaxial growth, deposition, photolithography, etching, and/or another semiconductor processing technique. The source/drain regions 210 cover the inner spacers 324, as shown in the example in FIG. 3L.

The material (e.g., silicon (Si), gallium (Ga), or another type of semiconductor material) that is used to form the source/drain regions 210 may be doped with a p-type dopant (e.g., a type of dopant that includes electron acceptor atoms that create holes in the material), with an n-type dopant (e.g., a type of dopant that includes electron donor atoms that create mobile electrons in the material), and/or with another type of dopant. The material may be doped by adding impurities (e.g., the p-type dopant, the n-type dopant) to a source gas that is used during the epitaxial operation. Examples of p-type dopants that may be used in the epitaxial operation include boron (B) or germanium (Ge), among other examples. The resulting material of p-type source/drain regions include silicon germanium (SiₓGe₁₋ₓ, where x can be in a range from approximately 0 to approximately 100) or another type of p-doped semiconductor material. Examples of n-type dopants that may be used in the epitaxial operation include phosphorous (P) or arsenic (As), among other examples. The resulting material of n-type source/drain regions include silicon phosphide (SiₓP_{y}) or another type of n-doped semiconductor material.

FIGS. 3M and 3N respectively illustrate a perspective view of the semiconductor device 200 and a cross-sectional view along the line B-B in FIG. 3M. As shown in FIGS. 3M and 3N, the dummy gate structures 312 are removed, leaving behind the spacer layers 318. The dummy gate structures 312 are removed as part of replacement gate process to replace the dummy gate structures 312 with replacement gate structures (e.g., metal gate (MG) structures, high-k metal gate structures, among other examples). The etch tool 108 may remove the dummy gate structures 312 using an etch technique, such as a plasma dry etch technique, a wet etch technique, and/or another etch technique. In some implementations, the dielectric layer 214 is formed (e.g., by the deposition tool 102) over the source/drain regions 210 prior to removal of the dummy gate structures 312. The dielectric layer 214 protects the source/drain regions 210 from etching and plasma damage that might otherwise occur in the operations to remove the dummy gate structures 312.

Removal of the dummy gate structures 312 exposes the channels 208 between the spacer layers 318. This enables the replacement gate structures to be formed around the channels 208 (e.g., on all 4 sides around the channels 208) in the areas that the first layers 304 previously occupied between the channels 208. The channels 208 include nanowire structures. The term nanowire is used herein to designate any material portion with nanoscale, or even microscale dimensions, and having an elongated shape, regardless of the cross-sectional shape of this portion. Thus, the term nanowire, as used herein, designates circular (or substantially circular) cross-sectionally elongated material portions, beam or bar-shaped material portions including for example a cylindrical shape or a substantially rectangular cross-section, and/or another similar shape.

As indicated above, FIGS. 3A-3N are provided as one or more examples. Other examples may differ from what is described with regard to FIGS. 3A-3N.

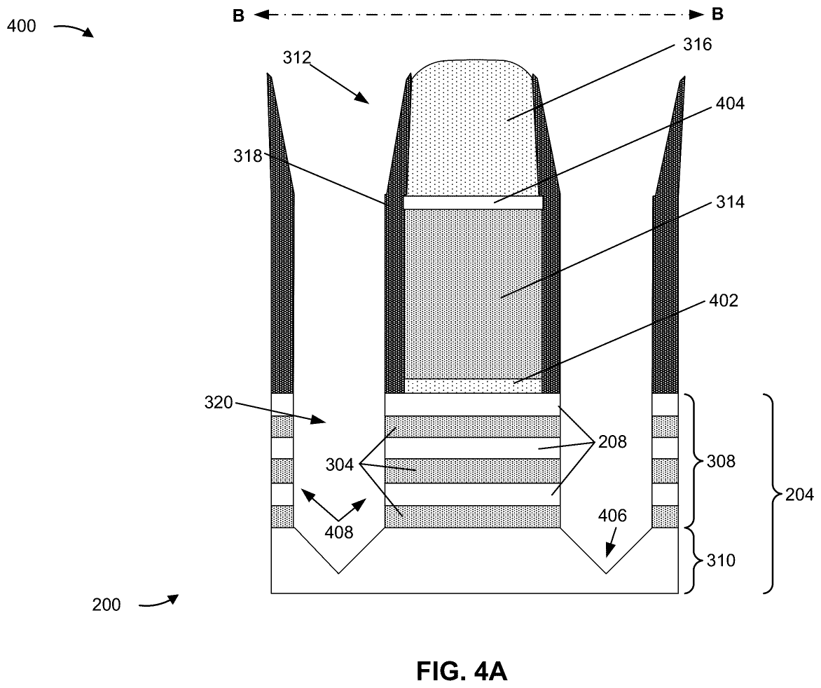

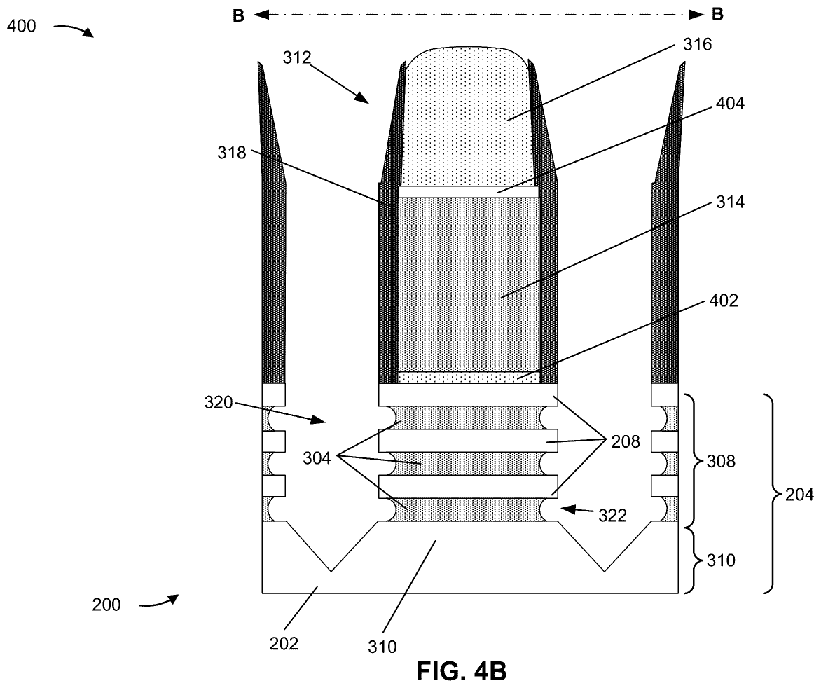

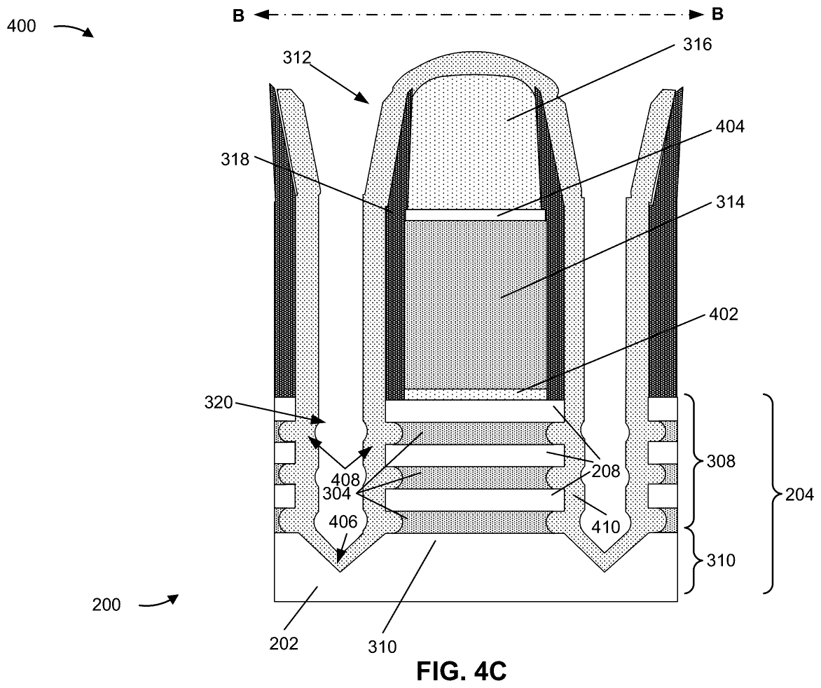

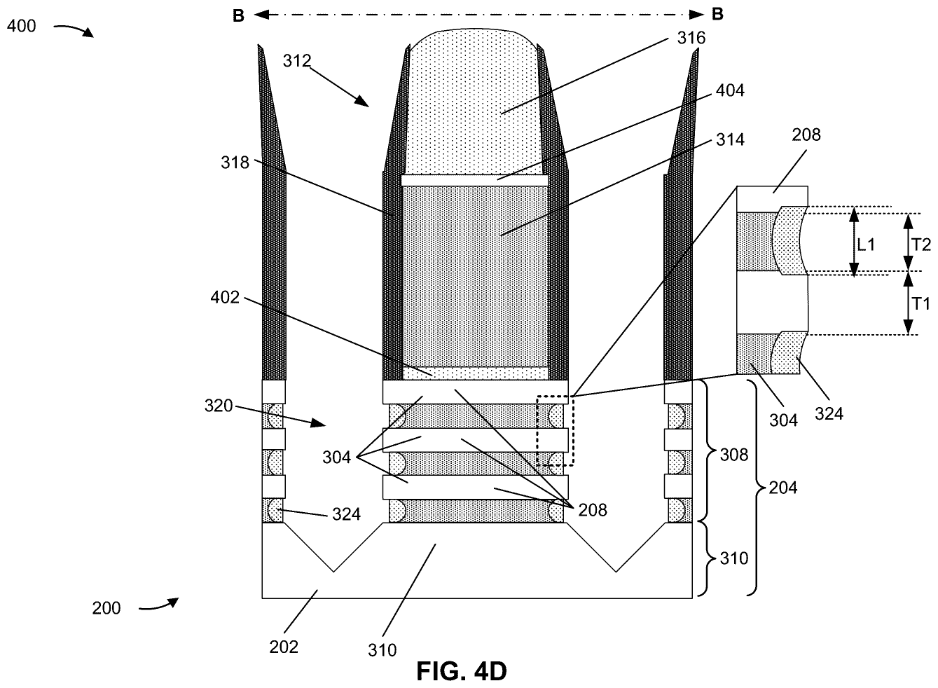

FIGS. 4A-4D are diagrams of an example implementation 400 described herein. The example implementation 400 includes an example of forming inner spacers in source/drain recesses 320 in the source/drain areas of the semiconductor device 200. FIGS. 4A-4D are illustrated from the perspective of the cross-sectional plane B-B in FIGS. 3G-3N.

As shown in FIG. 4A, in some implementations, the process to form the inner spacers may be performed after dummy gate structures 312 of the semiconductor device 200 are formed and after source/drain recesses 320 are formed. The dummy gate structures 312 may include a gate electrode layer 314, a hard mask layer 316, and spacer layers 318. The dummy gate structures 312 may further include a gate dielectric layer 402 between the gate electrode layer 314 and the alternating layers of the first layers 304 and the channels 208. The gate dielectric layer 402 may include a silicon oxide (e.g., SiOₓ such as SiO₂), a silicon nitride (e.g., SiₓN_{y} such as Si₃N₄), a high-K dielectric material and/or other suitable material. The dummy gate structures 312 may further include another hard mask layer 404.

In some implementations, the gate dielectric layer 402 is conformally deposited on the semiconductor device 200 and then selectively removed from portions of the semiconductor device 200 (e.g., the source/drain areas). The gate electrode layer 314 is deposited onto the gate dielectric layer 402 (e.g., before or after the gate dielectric layer 402 is etched). The hard mask layers 316 and 404 are deposited onto the gate electrode layer 314. The spacer layers 318 are conformally deposited in a similar manner as the gate dielectric layer 402.

As further shown in FIG. 4A, the spacer layers 318 may be tapered or angled as a result of an etch operation to form the source/drain recesses 320 and/or an etch operation to form the gate dielectric layer 402. In particular, the spacer layers 318 may be tapered or angled such that the width of the spacer layers 318 increases from a top of the spacer layers 318 (e.g., near the top of the hard mask layer 316) downward toward the gate electrode layer 314.

As further shown in FIG. 4A, the source/drain recesses 320 are formed into portions 308 of a fin structure 204. The etch tool 108 may etch the portions 308 using an etch technique, such as a wet etch technique, a dry etch technique, and/or a plasma-based etch technique, among other examples. The source/drain recesses 320 may extend or penetrate into portions 310 of the fin structure (e.g., such that the tops of the portions 310 are etched to below the tops of the STI regions 206), into a well portion (e.g., a p-well, an n-well) of the fin structure 204, and/or into another area of the fin structure 204. The source/drain recesses 320 include a bottom 406 and sidewalls 408.

In implementations in which the substrate 202 includes a silicon (Si) material having a (100) orientation, (111) faces are formed at the bottom 406 of the source/drain recesses 320, resulting in formation of a V-shape or a triangular shape cross section at the bottom 406 of the source/drain recesses 320. In some embodiments, a wet etching using tetramethylammonium hydroxide (TMAH) and/or a chemical dry etching using hydrochloric acid (HCl) are employed to form the V-shape profile.

As further shown in FIG. 4A, portions of the first layers 304 and portions of the second layers 306 remain under the dummy gate structures 312 after the etch operation to form the source/drain recesses 320. The portions of the second layers 306 under the dummy gate structures 312 form the channels 208 (e.g., nanostructure channels) of the nanostructure transistors of the semiconductor device 200.

As shown in FIG. 4B, the first layers 304 are laterally etched (e.g., in a direction that is approximately parallel to a length of the first layers 304) in an etch operation, thereby forming cavities 322 between portions of the channels 208. In particular, the etch tool 108 laterally etches ends of the first layers 304 under the dummy gate structure 312 through the source/drain recesses 320 to form the cavities 322 between ends of the channels 208. In implementations where the first layers 304 are silicon germanium (SiGe) and the second layers 306 are silicon (Si), the etch tool 108 may selectively etch the first layers 304 using a wet etchant such as, a mixed solution including hydrogen peroxide (H₂O₂), acetic acid (CH₃COOH), and/or hydrogen fluoride (HF), followed by cleaning with water (H₂O). The mixed solution and the wafer may be provided into the source/drain recesses 320 to etch the first layers 304 from the source/drain recesses 320. In some embodiments, the etching by the mixed solution and cleaning by water is repeated approximately 10 to approximately 20 times. The etching time by the mixed solution is in a range from about 1 minute to about 2 minutes in some implementations. The mixed solution may be used at a temperature in a range of approximately 60° Celsius to approximately 90° Celsius. However, other values for the parameters of the etch operation are within the scope of the present disclosure.

The cavities 322 may be formed to an approximately curved shape. In some implementations, the depth of one or more of the cavities 322 (e.g., the dimension of the cavities extending into the first layers 304 from the source/drain recesses 320) is in a range of approximately 0.5 nanometers to about 5 nanometers. In some implementations, the depth of one or more of the cavities 322 is in a range of approximately 1 nanometer to approximately 3 nanometers. However, other values for the depth of the cavities 322 are within the scope of the present disclosure.

The etch tool 108 forms the cavities 322 to a length (e.g., the dimension of the cavities extending from a channel 208 below a first layer 304 to another channel 208 above the first layer 304) such that the cavities 322 partially extend into the ends of the channels 208 (e.g., such that the width or length of the cavities 322 are greater than the thickness of the first layers 304). In this way, the inner spacers that are to be formed in the cavities 322 may extend into a portion of the ends of the channels 208.

As shown in FIG. 4C, an insulating layer 410 is conformally deposited along the bottom 406 and along the sidewalls 408 of the source/drain recesses 320. The insulating layer 410 further extends along the spacer layer 318 and over the hard mask layer 316. The deposition tool 102 may deposit the insulating layer 410 using a CVD technique, a PVD technique, and ALD technique, and/or another deposition technique. The insulating layer 410 includes a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another dielectric material. The insulating layer 410 may include a material that is different from the material of spacer layers 318.

The deposition tool 102 forms the layer 410 to a thickness sufficient to fill in the cavities 322 between the channels 208 with the layer 410. For example, the insulating layer 410 may be formed to a thickness in a range of approximately 1 nanometer to approximately 10 nanometers. As another example, the insulating layer 410 is formed to a thickness in a range of approximately 2 nanometers to approximately 5 nanometers. However, other values for the thickness of the insulating layer 410 are within the scope of the present disclosure.

As shown in FIG. 4D, the insulating layer 410 is partially removed to form inner spacers 324 in the cavities 322. The etch tool 108 may perform an etch operation to partially remove the insulating layer 410. As shown in a close-up view in FIG. 4D, the etch operation may result in the surfaces of the inner spacers 324 facing the source/drain recesses 320 being curved or recessed. The depth of the recesses may be in a range of approximately 0.2 nanometers to approximately 3 nanometers. As another example, the depth of the recesses may be in a range of approximately 0.5 nanometers to approximately 2 nanometers. As another example, the depth of the recesses may be in a range of less than approximately 0.5 nanometers. In some implementations, the surfaces of the inner spacers 324 facing the source/drain recesses 320 are approximately flat such that the surfaces of the inner spacers 324 and the surfaces of the ends of the channels 208 are approximately even and flush.

As further shown in the close-up view in FIG. 4D, the inner spacers 324 are formed to a length (L1) that is lesser relative to a thickness (T1) of the channels 208. The length (L1) being less than the thickness (T1) of the channels 208 reduces the likelihood of non-growth during epitaxial growth of the source/drain regions 210 (which may result in a non-merged source/drain region 210 and/or voids in a source/drain region 210). The inner spacers 324 are also formed such that the length (L1) is greater relative to a thickness (T2) of the first layers 304. As a result, the inner spacers 324 extend into portions of the channels 208 on opposing ends of the inner spacers 324, as shown in the close-up view in FIG. 4D. This provides increased isolation and reduced leakage between source/drain regions that are to be formed in the source/drain recesses 320 and gate structures 212 that are to be formed around the channels 208.

In some implementations, the thickness (T1) of the channels 208 is in a range of approximately 8 nanometers to approximately 12 nanometers to permit reduced device sizes in the semiconductor device 200 while maintaining sufficient device performance. However, other values for the thickness (T1) are within the scope of the present disclosure. In some implementations, the thickness (T2) of the first layers 304 is in a range of approximately 4 nanometers to approximately 7 nanometers to permit reduced device sizes in the semiconductor device 200 while providing sufficient area in which to form the gate structures 212. However, other values for the thickness (T2) are within the scope of the present disclosure. The thickness (T1) may be greater relative to the thickness (T2). In some implementations, a ratio of the thickness (T1) to the thickness (T2) is in a range of approximately 1.2 to approximately 1.8 to provide sufficient area for formation of the gate structures 212 while providing sufficient channel performance. However, other values for the ratio are within the scope of the present disclosure. In some implementations, a difference between the thickness (T1) and the thickness (T2) is in a range of approximately 1 nanometer to approximately 5 nanometers. However, other values for the difference are within the scope of the present disclosure.

In some implementations, the length (L1) of the inner spacers 324 is in a range of approximately 6 nanometers to approximately 8 nanometers to provide sufficient gate-to-source/drain isolation and to reduce the likelihood of void formation in the source/drain regions 210. In particular, the likelihood of void formation resulting from non-growth and/or non-merged layers in the source/drain regions 210 may greatly increase as the length (L1) increases above 8 nanometers. However, other values for the length (L1) are within the scope of the present disclosure. As described above, the inner spacers 324 may be formed such that the length (L1) is greater relative to the thickness (T2) of the first layers 304. In some implementations, a ratio of the length (L1) to the thickness (T2) is in a range of approximately 1.05 to approximately 1.5 to minimize residual silicon germanium (SiGe) that remains after removing the first layers 304, to maintain sufficient channel 208 width for device performance, and to reduce the likelihood of void formation in the source/drain regions 210. However, other values for the ratio are within the scope of the present disclosure. In some implementations, a difference between the length (L1) and the thickness (T2) is in a range of approximately 0.1 nanometers to approximately 2 nanometers. However, other values for the difference are within the scope of the present disclosure.

As indicated above, FIGS. 4A-4D are provided as one or more examples. Other examples may differ from what is described with regard to FIGS. 4A-4D.

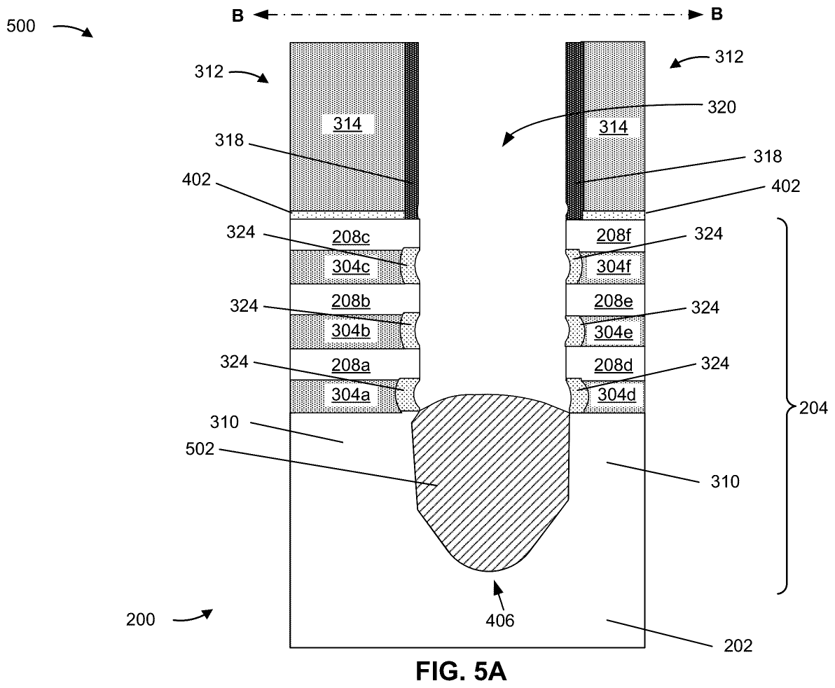

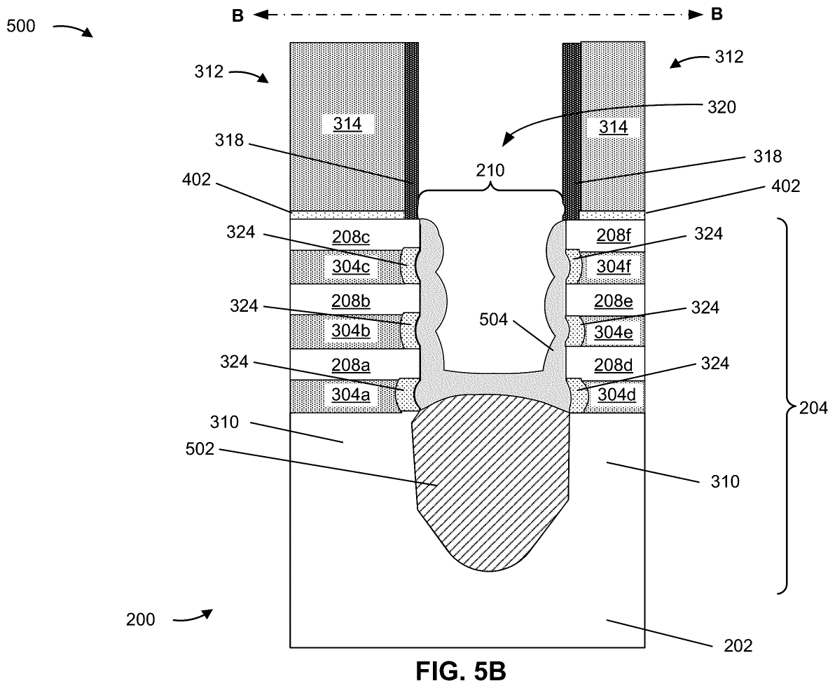

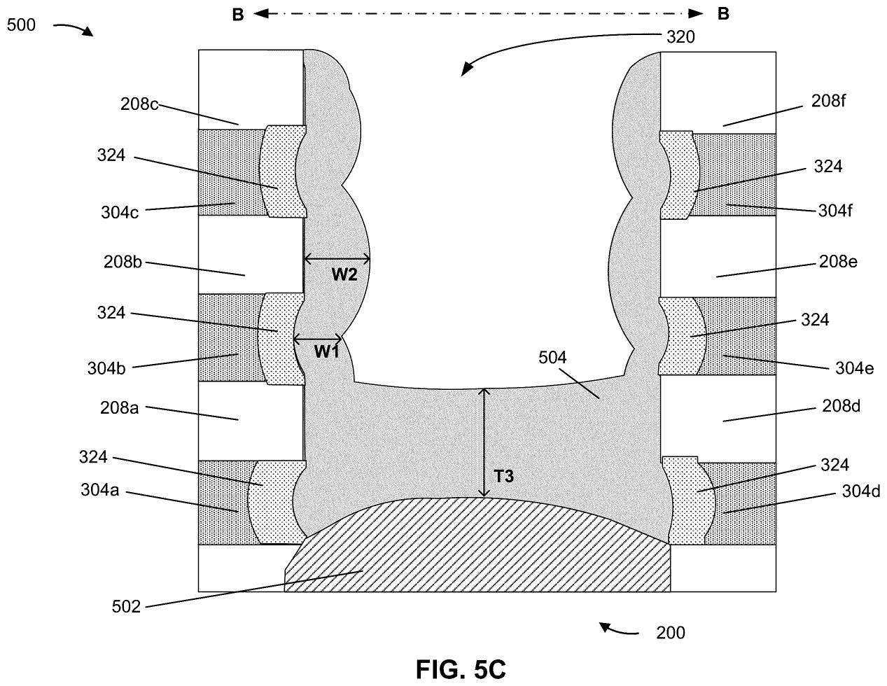

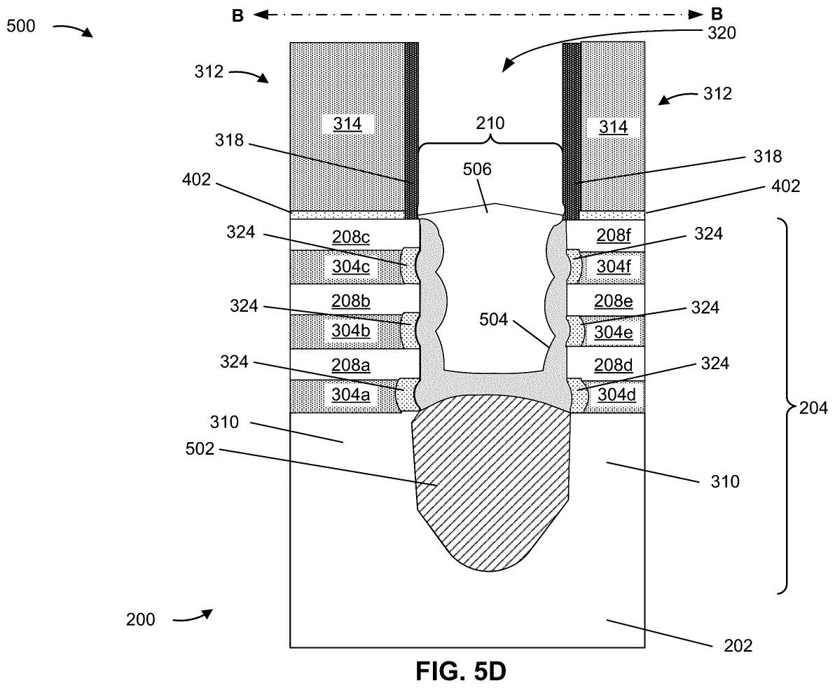

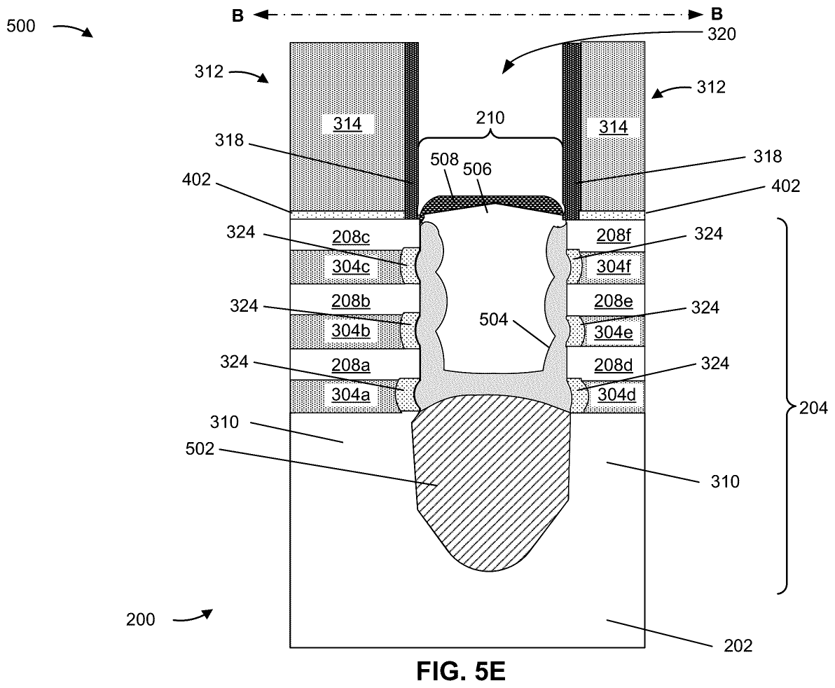

FIGS. 5A-5E are diagrams of an example implementation 500 described herein. The example implementation 500 includes an example of forming source/drain regions 210 in the source/drain recesses 320 of the semiconductor device 200. In particular, the example implementation 500 includes an example of forming multiple layer source/drain regions 210 to reduce the likelihood of void formation and/or to reduce the likelihood of nodule formation in the source/drain regions 210. FIGS. 5A-5E are illustrated from the perspective of the cross-sectional plane B-B in FIGS. 3G-3N.

As shown in FIG. 5A, the operations described in connection with FIGS. 5A-5E may be performed after formation of the inner spacers 324 in the cavities 322. The first layers 304 may include first layers 304a-304f. However, the first layer 304 may include greater or fewer layers. The channels 208 may include channels 208a-208f. However, the channels 208 may include greater or fewer layers. Respective inner spacer 324 may be included between each of the first layers 304 and a source/drain recess 320 of the semiconductor device 200.

As further shown in FIG. 5A, a buffer layer 502 is formed on the bottom 406 of the source/drain recess 320. The buffer layer 502 may be considered a part of a source/drain region 210, or a separate layer on which a source/drain region 210 is formed. The buffer layer 502 may be included in the source/drain recess 320 to reduce current leakage and/or dopant diffusion under a source/drain region 210 that is to be formed in the source/drain recess 320 and into the mesa regions (e.g., the portions 310) of the fin structure 204. Accordingly, the buffer layer 502 is formed such that the sidewalls of the buffer layer 502 fully cover the sidewalls of the mesa regions of the fin structure 204 so that there are no gaps (which might otherwise result in current leakage and/or dopant diffusion) between the buffer layer 502 and the bottom-most inner spacers 324 in the source/drain recess 320. In some implementations, the buffer layer 502 is included to control the proximity and/or shape of the source/drain region 210.

The deposition tool 102 may deposit the buffer layer 502 using a CVD technique, a PVD technique, an ALD technique, an epitaxial growth technique, and/or another deposition technique. Deposition of the buffer layer 502 may be performed at a temperature in a range of approximately 650 degrees Celsius to approximately 750 degrees Celsius, may be performed at a pressure in a range of approximately 10 torr to approximately 300 torr, and/or using one or more other processing parameters. Precursors and/or process gasses that may be used in the deposition of the buffer layer 502 include germanium tetrahydride (GeH₄), hydrochloric acid (HCl), silicon tetrahydride (SiH₄), dichlorosilane (DCS or SiH₂Cl₂), phosphine (PH₃), diborane (B₂H₆), boron trichloride (BCl₃), hydrogen (H₂), and/or nitrogen (N₂), among other examples. In some implementations, the buffer layer 502 is formed such that a top surface of the buffer layer 502 exposed in the source/drain recess 320 includes a (100) grain orientation.

The buffer layer 502 may include silicon (Si), silicon germanium (SiGe), silicon doped with boron (SiB) or another dopant, and/or another material. In implementations in which the buffer layer 502 includes silicon germanium, the germanium (Ge) concentration in the buffer layer 502 may be in a range of approximately 1% germanium to approximately 10% germanium. However, other values for the germanium concentration are within the scope of the present disclosure.

As shown in FIG. 5B, a first layer 504 of the source/drain region 210 is formed in the source/drain recess 320 over and/or on the buffer layer 502. The first layer 504 is formed on the inner spacers 324 in the source/drain recess 320, and on the ends of the channels 208 in the source/drain recess 208. The first layer 504 is formed such that the topmost channels 208 in the source/drain recess (e.g., the channels 208c and 208f) are fully covered by the first layer 504 to minimize and/or prevent dopant leakage into the topmost channels 208. The first layer 504 may be included to function as a shielding layer to reduce short channel effects in the semiconductor device 200 and to reduce dopant extrusion into the channels 208. The first layer 504 is conformally deposited at the bottom of the source/drain recess and on the sidewalls of the source/drain recess 320 (e.g., on the ends of the channels 208 and on the inner spacers 324). As described herein, the inner spacers 324 are formed to a length (L1) to reduce the likelihood of void formation in the first layer 504. Accordingly, the first layer 504 includes a continuous layer of material on the bottom of the source/drain recess 320 and along the sidewalls of the source/drain recess 320 as a result of the length (L1) of the inner spacers 324.

The deposition tool 102 may deposit the first layer 504 using a CVD technique, a PVD technique, an ALD technique, an epitaxial growth technique, and/or another deposition technique. Deposition of the first layer 504 may be performed at a temperature in a range of approximately 600 degrees Celsius to approximately 700 degrees Celsius, may be performed at a pressure in a range of approximately 10 torr to approximately 300 torr, and/or using one or more other processing parameters. Precursors and/or process gasses that may be used in the deposition of the first layer 504 include germanium tetrahydride (GeH₄), hydrochloric acid (HCl), silicon tetrahydride (SiH₄), dichlorosilane (DCS or SiH₂Cl₂), phosphine (PH₃), diborane (B₂H₆), boron trichloride (BCl₃), hydrogen (H₂), and/or nitrogen (N₂), among other examples.

The deposition tool 102 and the etch tool 108 may perform a plurality of deposition and etch cycles to form the first layer 504. Each deposition and etch cycle includes a deposition operation and an etch operation. In some implementations, the deposition operation is performed first and the etch operation is performed second. In some implementations, the etch operation is performed first and the deposition operation is performed second. In some implementations, the deposition tool 102 and the etch tool 108 perform a quantity of deposition and etch cycles that is in a range of approximately 50 cycles to approximately 60 cycles to form the first layer 504 to a sufficient thickness, and such that a continuous layer of materials is formed for the first layer 504 without forming the first layer 504 too thick so as to cause issues with filling the remainder of the source/drain region 210 in the source/drain recess 320.

The deposition operation may include the deposition tool 102 depositing one or more silicon precursors (e.g., silicon tetrahydride (SiH₄) and/or another silicon precursor), one or more germanium precursors (e.g., germanium tetrahydride (GeH₄) and/or another germanium precursor), and/or one or more dopants (e.g., diborane (B₂H₆) and/or another dopant) using a process gas (e.g., hydrogen (H₂) and/or another process gas). The etch operation may include the etch tool 108 using an etchant such as hydrochloric acid (HCl) and/or another etchant. The combination of deposition operations and etch operations in a cyclical manner increases control over the continuity of the first layer 504 and control over the thickness of the first layer 504. In particular, the use of silicon tetrahydride as a silicon precursor in the deposition operation increases the deposition rate of the first layer 504 increases the likelihood of forming a continuous layer of material for the first layer 504, and use of hydrochloric acid as an etchant facilitates maintaining a relatively low thickness for the first layer 504.

In some implementations, a combination of silicon tetrahydride and dichlorosilane (DCS or SiH₂Cl₂) is used to deposit the first layer 504. In these implementations, a ratio of silicon tetrahydride to dichlorosilane may be in a range of greater than approximately 5:1 to approximately 7:1 to increase the likelihood of forming a continuous layer of material for the first layer 504. However, other values for the ratio are within the scope of the present disclosure. In implementations in which a ratio between a dopant (e.g., diborane) and silicon precursor is in a particular range (e.g., approximately 0.1:1 to approximately 0.3:1 or another range), the ratio of dichlorosilane to silicon tetrahydride may be in a range of approximately 5:1 to approximately 10:1 to reduce defect formation and to provide sufficient deposition selectivity. However, other values for the ratio are within the scope of the present disclosure.

In some implementations, a deposition operation and an etch operation of a deposition and etch cycle may be performed using the same processing parameters (e.g., the same pressure, the same temperature). In some implementations, a deposition operation and an etch operation of a deposition and etch cycle may be performed using different processing parameters. For example, the etch operation may be performed at a greater temperature relative to the deposition operation. As another example, the etch operation may be performed at a greater pressure relative to the deposition operation. In some implementations, the deposition operation is performed at a temperature in a range of approximately 600 degrees Celsius to approximately 650 degrees Celsius whereas the etch operation is performed at a temperature in a range of approximately 630 degrees Celsius to approximately 680 degrees Celsius. However, other values for the temperatures of the deposition operation and the etch operation are within the scope of the present disclosure. In some implementations, the etch operation is performed at approximately twice the pressure as the deposition operation to control the etch direction in the etch operation.

The first layer 504 may include silicon (Si), silicon germanium (SiGe), doped silicon (e.g., silicon doped with arsenic (SiAs) or another dopant), doped silicon germanium (e.g., silicon germanium doped with boron (SiGe:B) or another dopant), and/or another material. In implementations in which the first layer 504 includes silicon germanium, the germanium (Ge) concentration in the first layer 504 may be in a range of approximately 20% germanium to approximately 40% germanium. However, other values for the germanium concentration are within the scope of the present disclosure. The first layer 504 may include a lightly doped layer. For example, the doping concentration of arsenic (As) of the first layer 504 (e.g., where the first layer 504 includes silicon) may be in a range of approximately 5×10²⁰ atoms per cubic centimeter to approximately 2×10²¹ atoms per cubic centimeter. As another example, the doping concentration of boron (B) of the first layer 504 (e.g., where the first layer 504 includes silicon germanium) may be in a range of approximately 1×10²⁰ atoms per cubic centimeter to approximately 8×10²⁰ atoms per cubic centimeter. However, other values for the dopant range are within the scope of the present disclosure.

As shown in FIG. 5C, the first layer 504 is formed over the buffer layer 502 to a thickness (T3) such that the first layer 504 is continuous across the cross section of the source/drain recess 320 at a height that is approximately equal to or greater than a height of the lowest channels 208 (e.g., channel 208a and channel 208d) of the fin structure 204. In some implementations, the thickness (T3) of the first layer 504 is in a range of approximately 5 nanometers to approximately 10 nanometers to ensure that the first layer 504 is continuous across the cross section of the source/drain recess 320 at a height that is approximately equal to or greater than a height of the lowest channels 208. However, other values for the thickness (T3) are within the scope of the present disclosure.

As further shown in FIG. 5C, a width (W1) of the first layer 504 over the inner spacers 324 of the sidewalls of the source/drain recess 320 is lesser relative to a width (W2) of the first layer over the channels 208 of the sidewalls of the source/drain recess 320. In some implementations, a ratio of the width (W2) to the width (W1) is in a range of approximately 1.2:1 to approximately 2:1 to achieve a sufficiently low thickness for the first layer 504 while increasing the likelihood of forming a continuous layer of material for the first layer 504. However, other values for the range are within the scope of the present disclosure. However, other values for the ratio are within the scope of the present disclosure. In some implementations, the width (W1) and/or the width (W2) are in a range of approximately 3 nanometers to approximately 6 nanometers. In some implementations, the width (W1) and/or the width (W2) are in a range of approximately 5 nanometers to approximately 10 nanometers. The total cross-sectional width of the source/drain recess 320 (referred to as a critical dimension (CD)) occupied by the width of the first layer 504 is in a range of approximately 5% to approximately 20%.

As shown in FIG. 5D, a second layer 506 of the source/drain region 210 is formed in the source/drain recess 320 over and/or on the first layer 504 of the source/drain region 210. The second layer 506 may be included to provide a compressive stress in the source/drain region 210 to reduce boron loss. In some implementations, the second layer 506 is formed such that a height of a top surface of the second layer 506 and a height of a top surface of the top-most channels 208 (e.g., the channel 208c, the channel 208f) is approximately equal. In some implementations, the second layer 506 is formed such that a height of a top surface of the second layer 506 is greater relative to the height of the top surface of the top-most channels 208. In some implementations, the second layer 506 is formed such that a height of a top surface of the second layer 506 is lesser relative to the height of the top surface of the top-most channels 208.

The deposition tool 102 may deposit the second layer 506 using a CVD technique, a PVD technique, an ALD technique, an epitaxial growth technique, and/or another deposition technique. Deposition of the second layer 506 may be performed at a temperature in a range of approximately 600 degrees Celsius to approximately 700 degrees Celsius, may be performed at a pressure in a range of approximately 10 torr to approximately 300 torr, and/or using one or more other processing parameters. Precursors and/or process gasses that may be used in the deposition of the second layer 506 include germanium tetrahydride (GeH₄), hydrochloric acid (HCl), silicon tetrahydride (SiH₄), dichlorosilane (DCS or SiH₂Cl₂), phosphine (PH₃), diborane (B₂H₆), boron trichloride (BCl₃), hydrogen (H₂), and/or nitrogen (N₂), among other examples.

The second layer 506 may include silicon (Si), silicon germanium (SiGe), doped silicon (e.g., silicon doped with phosphorous (SiP) or another dopant), doped silicon germanium (e.g., silicon germanium doped with boron (SiGe:B) or another dopant), and/or another material. In some implementations, the first layer 504 and the second layer 506 are formed of the same material. In some implementations, the first layer 504 and the second layer 506 are formed of different materials. In implementations in which the second layer 506 includes silicon germanium, the germanium (Ge) concentration in the second layer 506 may be in a range of approximately 40% germanium to approximately 60% germanium. However, other values for the germanium concentration are within the scope of the present disclosure. The second layer 506 may include a highly doped layer, and the doping concentration of the second layer 506 may be greater relative to the doping concentration of the first layer 504. For example, the doping concentration of boron (B) of the second layer 506 (e.g., where the second layer 506 includes silicon germanium) may be in a range of approximately 8×10²⁰ atoms per cubic centimeter to approximately 3×10²¹ atoms per cubic centimeter. As another example, the doping concentration of phosphor (P) of the second layer 506 (e.g., where the second layer 506 includes silicon) may be in a range of approximately 1×10²¹ atoms per cubic centimeter to approximately 5×10²¹ atoms per cubic centimeter. However, other values for the dopant range are within the scope of the present disclosure.

As shown in FIG. 5E, a capping layer 508 is formed in the source/drain recess 320 over and/or on the second layer 506 of the source/drain region 210. The capping layer 508 may be considered a part of the source/drain region 210 (e.g., an L3 layer of the source/drain region 210) or a separate layer from the source/drain region 210. The capping layer 508 may be included to reduce dopant diffusion and to protect the source/drain regions 210 in subsequent semiconductor processing operations for the semiconductor device 200 prior to contact formation.

The deposition tool 102 may deposit the capping layer 508 using a CVD technique, a PVD technique, an ALD technique, an epitaxial growth technique, and/or another deposition technique. Deposition of the capping layer 508 may be performed at a temperature in a range of approximately 600 degrees Celsius to approximately 700 degrees Celsius, may be performed at a pressure in a range of approximately 10 torr to approximately 300 torr, and/or using one or more other processing parameters. Precursors and/or process gasses that may be used in the deposition of the capping layer 508 include germanium tetrahydride (GeH₄), hydrochloric acid (HCl), silicon tetrahydride (SiH₄), dichlorosilane (DCS or SiH₂Cl₂), phosphine (PH₃), diborane (B₂H₆), boron trichloride (BCl₃), hydrogen (H₂), and/or nitrogen (N₂), among other examples.

The capping layer 508 may include silicon (Si), silicon germanium (SiGe), doped silicon (e.g., silicon doped with phosphorous (SiP) or another dopant), doped silicon germanium (e.g., silicon germanium doped with boron (SiGe:B) or another dopant), and/or another material. In implementations in which the capping layer 508 includes silicon germanium, the germanium (Ge) concentration in the capping layer 508 may be in a range of approximately 45% germanium to approximately 55% germanium. However, other values for the germanium concentration are within the scope of the present disclosure. The capping layer 508 may be referred to as a lightly doped layer in that doping concentration (e.g., the boron (B) doping concentration of silicon germanium) of the capping layer 508 may be in a range of approximately 1×10²¹ atoms per cubic centimeter to approximately 2×10²¹ atoms per cubic centimeter. However, other values for the dopant range are within the scope of the present disclosure.

As indicated above, FIGS. 5A-5E are provided as one or more examples. Other examples may differ from what is described with regard to FIGS. 5A-5E.

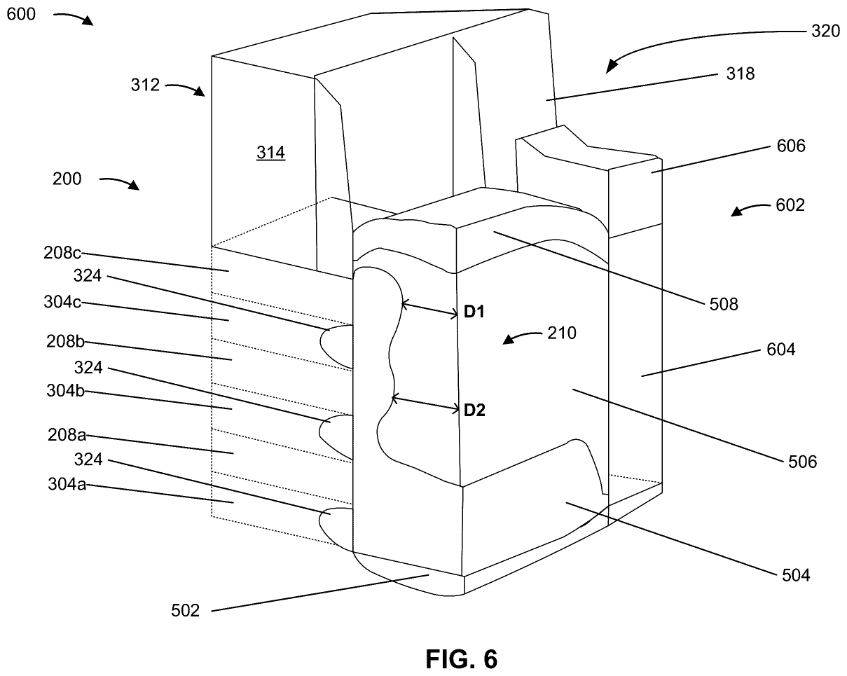

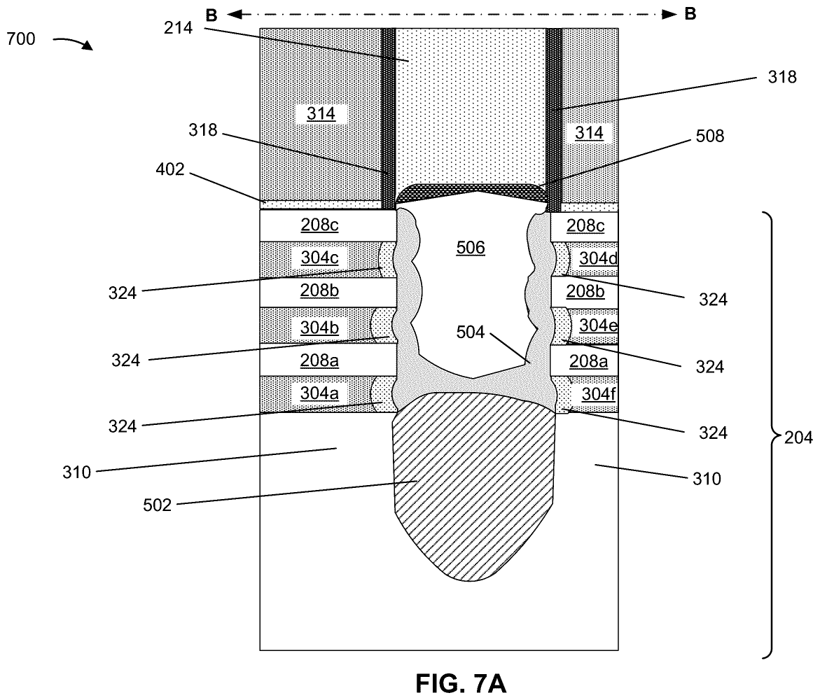

FIG. 6 is a diagram of a portion 600 of the semiconductor device 200 described herein. FIG. 6 illustrates a cut-away perspective view of the portion 600 including the channels 208, the first layers 304, a dummy gate structure 312, a plurality of inner spacers 324, a source/drain region 210 including the first layer 504 and the second layer 506, and a capping layer 508.

As further shown in FIG. 6, the first layer 504 may include a non-uniform width along the sidewalls of the source/drain recess 320. In particular, the width of the first layer 504 may decrease downward from a top of the first layer 504. As an example, a depth (D1) of the first layer 504 from the center of the source/drain region 210, at a height of a channel 208c (e.g., the top channel 208), is lesser relative to a depth (D2) of the first layer 504 from the center of the source/drain region at a height of a channel 208b (e.g., a middle channel 208 below the top channel 208) as a result of the first layer 504 being thicker near the top of the source/drain region 210. In some implementations, a ratio of the depth (D2) to the depth (D1) is in a range of approximately 0.6 to approximately 1.1 to reduce a likelihood of an early merge of the first layer 504 near the top of the source/drain recess 320 will reducing the likelihood of necking in the first layer 504. However, other values for the ratio are within the scope of the present disclosure. Conformal growth of the first layer 504 is greater at the bottom of the source/drain recess 320 relative to at the top of the source/drain recess 320, whereas the etch rate is greater at the bottom relative to the top, thereby resulting in the decreasing width of the first layer 504 from top to bottom. Also, dopant extrusion at the bottom is greater relative to dopant extrusion at the top.

As further shown in FIG. 6, in some implementations, the semiconductor device 200 includes hybrid fin structures 602. The hybrid fin structures 602 may also referred to as dummy fins, H-fins, or non-active fins, among other examples. Hybrid fin structures 602 may be included between adjacent fin structures 204 (e.g., between adjacent active fin structures). The hybrid fin structures 602 extend in a direction that is approximately parallel to the fin structures 204.

Hybrid fin structures 602 are configured to provide electrical isolation between two or more structures and/or components included in the semiconductor device 200. In some implementations, a hybrid fin structure 602 is configured to provide electrical isolation between two or more fin structures 204 (e.g., two or more active fin structures). In some implementations, a hybrid fin structure 602 is configured to provide electrical isolation between two or more source/drain regions 210. In some implementations, a hybrid fin structure 602 is configured to provide electrical isolation between two or more gates structures 212 (which replace the dummy gate structures 312) or two or more portions of a gate structure 212. In some implementations, a hybrid fin structure 602 is configured to provide electrical isolation between a source/drain region 210 and a gate structure 212.

A hybrid fin structure 602 may include a plurality of types of dielectric materials. A hybrid fin structure 602 may include a combination of one or more low dielectric constant (low-k) dielectric layer 604 (e.g., a silicon oxide (SiOₓ) and/or a silicon nitride (SiₓN_{y}), among other examples) and one or more high dielectric constant (high-k) dielectric layers 606 (e.g., a hafnium oxide (HfOₓ) and/or other high-k dielectric material) above the low-k dielectric layer 604.

As indicated above, FIG. 6 is provided as an example. Other examples may differ from what is described with regard to FIG. 6.

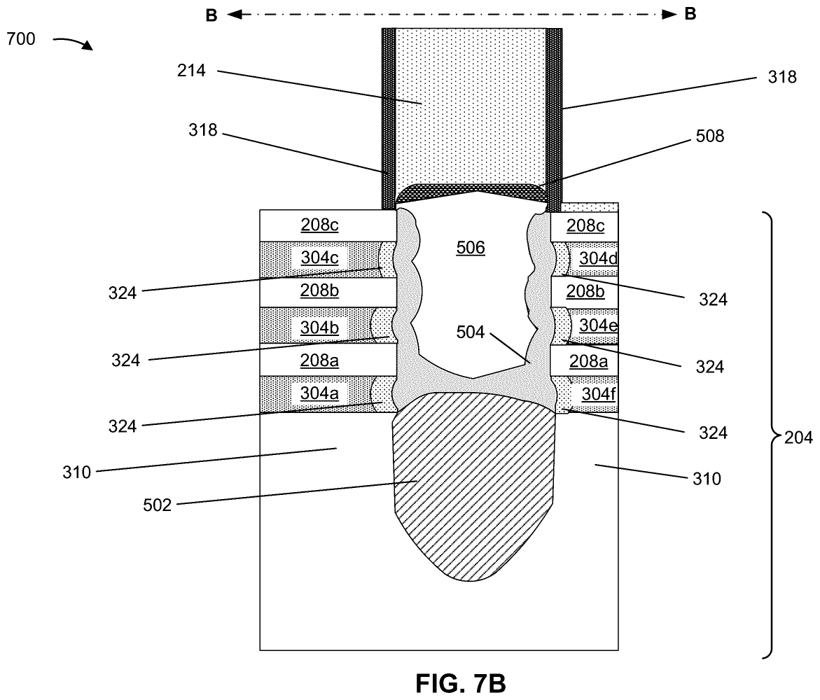

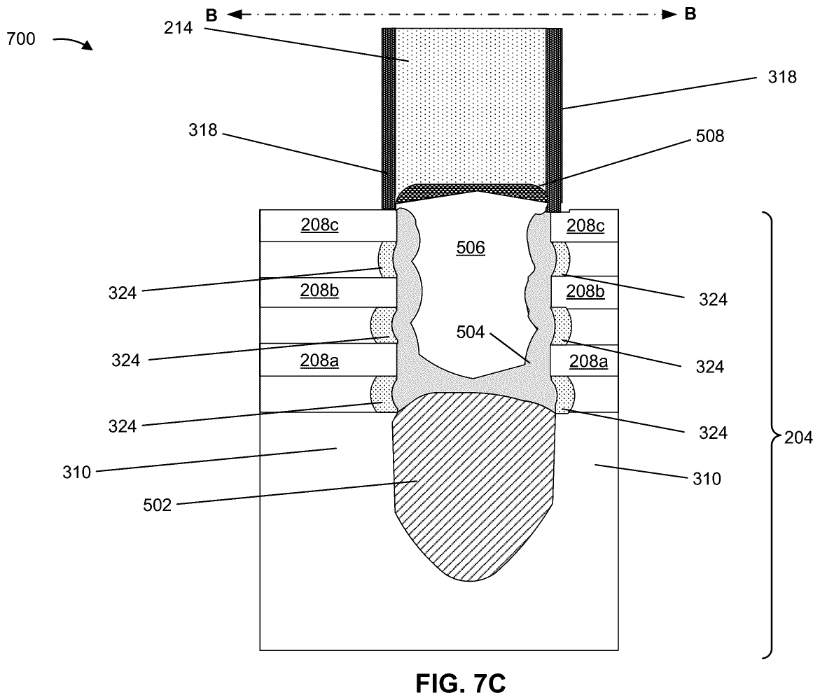

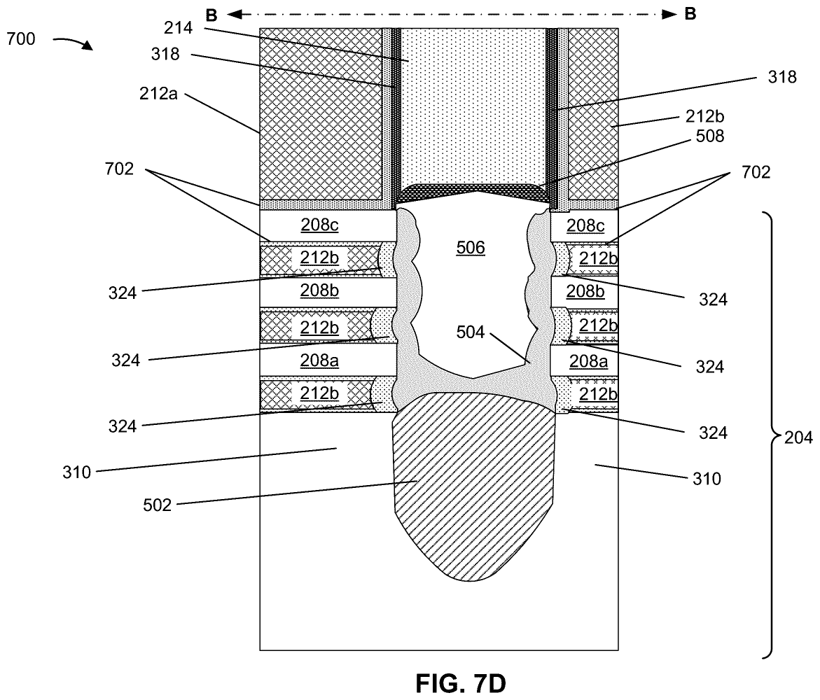

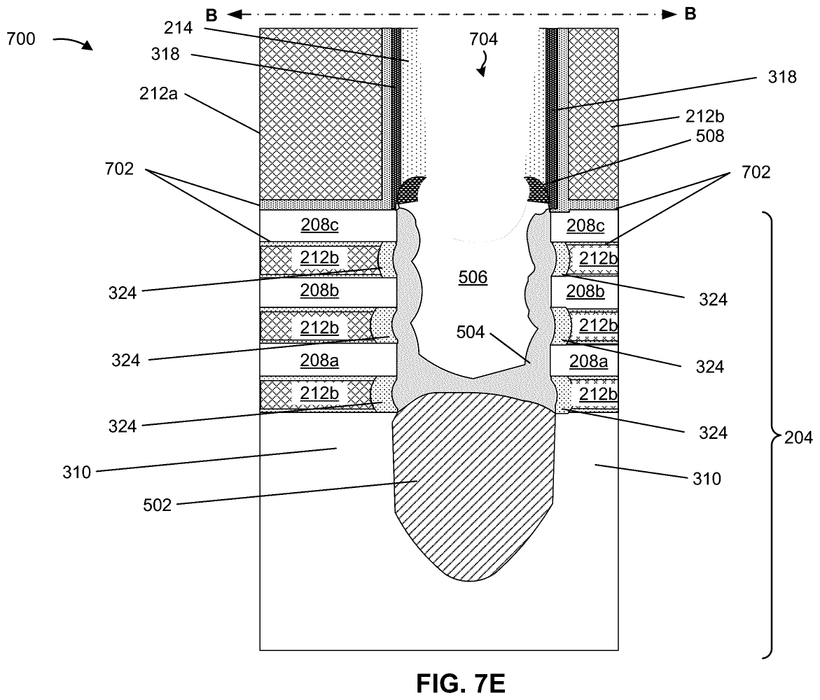

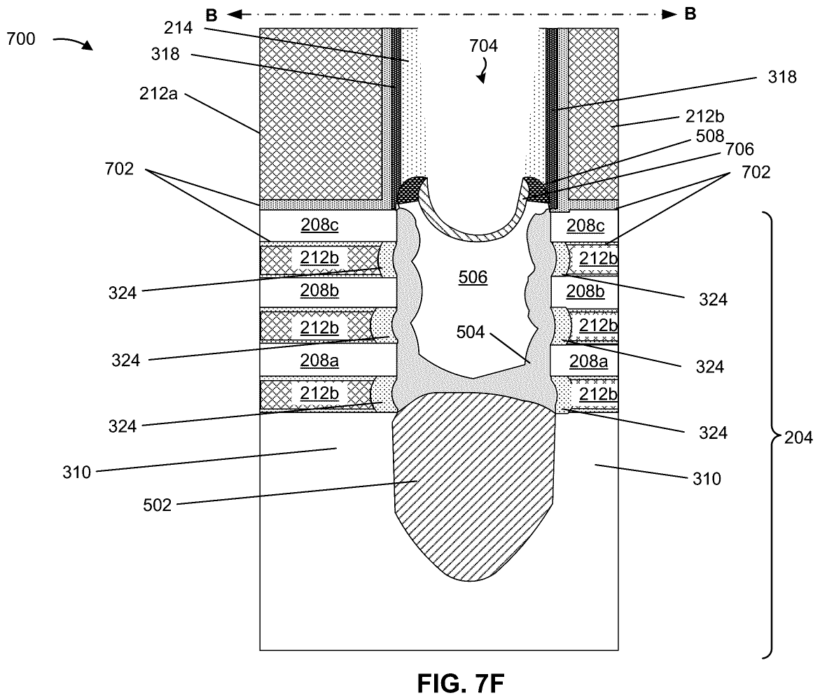

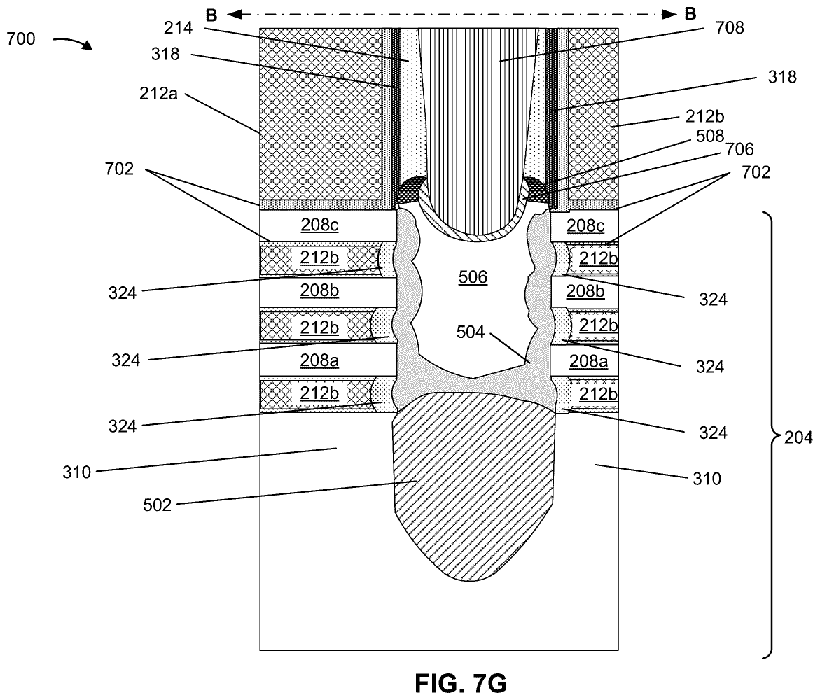

FIGS. 7A-7G are diagrams of an example implementation 700 described herein. The example implementation 700 includes an example replacement gate process (RGP) to replace the dummy gate structures 312 with gate structures 212 (e.g., high-k and/or metal gate structures), followed by a source/drain contact (MD) formation process. The processes described in connection with FIGS. 7A-7G may be performed after the operations described in connection with FIGS. 5A-5E to form the source/drain regions 210 of the semiconductor device 200. In some implementations, one or more operations described in connection with FIGS. 7A-7G are performed in connection with the operations described in connection with FIGS. 3M and 3N.

As shown in FIG. 7A, the dielectric layer 214 is formed over the source/drain regions 210. The dielectric layer 214 fills in areas between the dummy gate structures 312. The dielectric layer 214 is formed to reduce the likelihood of and/or prevent damage to the source/drain regions 210 during the replacement gate process. The dielectric layer 214 may be referred to as an interlayer dielectric (ILD) zero (ILDO) layer or another ILD layer. The deposition tool 102 may form the dielectric layer 214 using a deposition process, such as ALD, CVD, or another deposition technique.

In some implementations, a contact etch stop layer (CESL) is conformally deposited (e.g., by the deposition tool 102) over the source/drain regions 210, over the dummy gate structures 312, and on the spacer layers 318 prior to formation of the dielectric layer 214. The dielectric layer 214 is then formed on the CESL. The CESL may provide a mechanism to stop an etch process when forming contacts or vias for the source/drain regions 210. The CESL may be formed of a dielectric material having a different etch selectivity from adjacent layers or components. The CESL may include or may be a nitrogen containing material, a silicon containing material, and/or a carbon containing material. Furthermore, the CESL may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL may be deposited using a deposition process, such as ALD, CVD, or another deposition technique.

As shown in FIG. 7B, the dummy gate structures 312 are then removed from the semiconductor device 200. The removal of the dummy gate structures 312 leaves behind openings (or recesses) between the dielectric layer 214 over the source/drain regions 210. The dummy gate structures 312 may be removed in one or more etch operations including a plasma etch technique, which may include a wet chemical etch technique, and/or another type of etch technique.

As shown in FIG. 7C, a nanostructure release operation is also performed to remove the first layers 304 (e.g., the silicon germanium layers). This results in openings between the channels 208 (e.g., the areas around the channels 208 previously occupied by the first layers 304). The nanostructure release operation may include the etch tool 108 performing an etch operation to remove the first layer 304 based on a difference in etch selectivity between the material of the first layers 304 and the material of the channels 208, and between the material of the first layers 304 and the material of the inner spacers 324. The inner spacer 324 may function as etch stop layers in the etch operation to protect the source/drain regions 210 from being etched.

A cladding layer may be formed along the layer stack 302 (e.g., prior to formation of the dummy gate structures 312). The cladding layer may be formed of the same material as the first layers 304, and may provide a path for an etchant to reach the first layers 304 between the channels 208, when enables the nanostructure release operation to be performed.

As shown in FIG. 7D, the deposition tool 102 and/or the plating tool 112 forms the gate structures 212 (e.g., replacement gate structures) in the openings between the source/drain regions 210 and in the space above the channels 208 previously occupied by the dummy gate structures 312 and the first layers 304. In particular, a gate portion 212a fills the space above the channels 208 previously occupied by the dummy gate structures 312, and gate portions 212b fill the areas between and around the channels 208 such that the gate structures 212 surround the channels 208. The gate structures 212 are also formed in the areas that were previously occupied by the cladding layer, which enables the gate portions 212b to fully wrap around the channels 208. The gate structures 212 may include metal gate structures. A conformal high-k dielectric liner 702 may be deposited onto the channels 208 and on sidewalls of the dielectric layer 214 prior to formation of the gate structures 212. The gate structures 212 may include additional layers such as an interfacial layer, a work function tuning layer, and/or a metal electrode structure, among other examples.

As shown in FIGS. 7E-7G, a source/drain contact (referred to as an MD) is formed to the source/drain region 210 through the dielectric layer 214. As shown in FIG. 7E, to form the source/drain contact, a recess 704 is formed through the dielectric layer 214 and to the source/drain region 210. In some implementations, the recess 704 is formed in a portion of the source/drain region 210 such that the source/drain contact extends into a portion of the source/drain region 210.

In some implementations, a pattern in a photoresist layer is used to form the recess 704. In these implementations, the deposition tool 102 forms the photoresist layer on the dielectric layer 214 and on the gate structures 212. The exposure tool 104 exposes the photoresist layer to a radiation source to pattern the photoresist layer. The developer tool 106 develops and removes portions of the photoresist layer to expose the pattern. The etch tool 108 etches into the dielectric layer 214 to form the recess 704. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recess 704 based on a pattern.

As shown in FIG. 7F, a metal silicide layer 706 is formed on the source/drain region 210 in the recess 704 prior to forming the source/drain contact. The deposition tool 102 may form the metal silicide layer 706 to decrease contact resistance between the source/drain region 210 and the source/drain contact. Moreover, the metal silicide layer 706 may protect the source/drain region 210 from oxidization and/or other contamination. The metal silicide layer 706 includes a titanium silicide (TiSiₓ) layer or another type of metal silicide layer.

As shown in FIG. 7G, a source/drain contact 708 is then formed in the recess and on the metal silicide layer 706 over the source/drain region 210. The deposition tool 102 and/or the plating tool 112 deposits the source/drain contact 708 using a CVD technique, a PVD technique, an ALD technique, an electroplating technique, another deposition technique described above in connection with FIG. 1, and/or a deposition technique other than as described above in connection with FIG. 1. The source/drain contact 708 includes ruthenium (Ru), tungsten (W), cobalt (Co), and/or another metal.

As indicated above, FIGS. 7A-7G is provided as an example. Other examples may differ from what is described with regard to FIGS. 7A-7G.

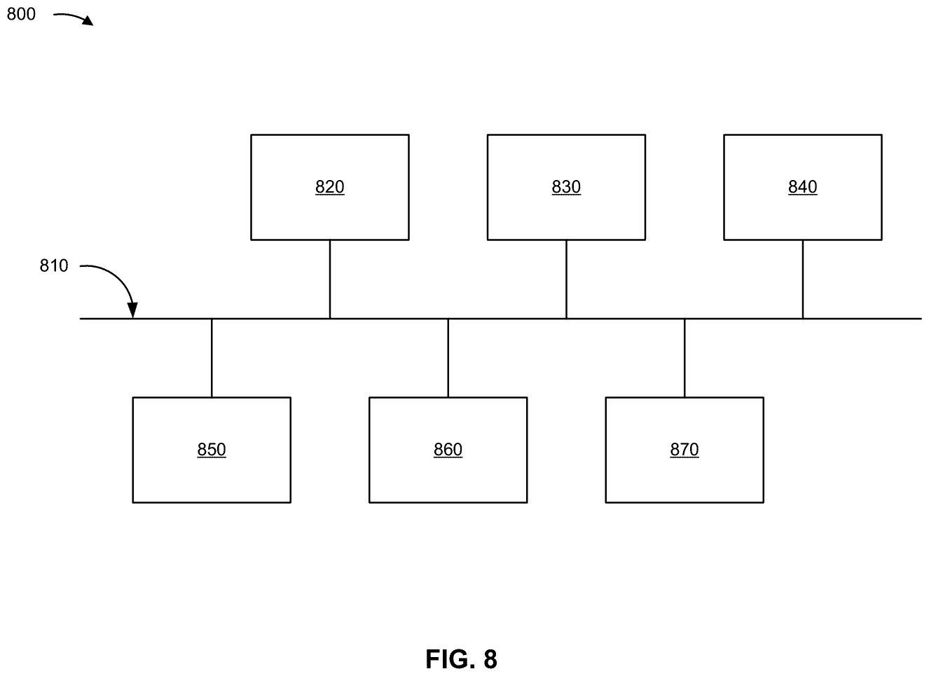

FIG. 8 is a diagram of example components of a device 800. In some implementations, one or more of the semiconductor processing devices 102-112 and/or the wafer/die transport tool 114 may include one or more devices 800 and/or one or more components of device 800. As shown in FIG. 8, device 800 may include a bus 810, a processor 820, a memory 830, an input component 840, an output component 850, and a communication component 860.

Bus 810 includes one or more components that enable wired and/or wireless communication among the components of device 800. Bus 810 may couple together two or more components of FIG. 8, such as via operative coupling, communicative coupling, electronic coupling, and/or electric coupling. Processor 820 includes a central processing unit, a graphics processing unit, a microprocessor, a controller, a microcontroller, a digital signal processor, a field-programmable gate array, an application-specific integrated circuit, and/or another type of processing component. Processor 820 is implemented in hardware, firmware, or a combination of hardware and software. In some implementations, processor 820 includes one or more processors capable of being programmed to perform one or more operations or processes described elsewhere herein.

Memory 830 includes volatile and/or nonvolatile memory. For example, memory 830 may include random access memory (RAM), read only memory (ROM), a hard disk drive, and/or another type of memory (e.g., a flash memory, a magnetic memory, and/or an optical memory). Memory 830 may include internal memory (e.g., RAM, ROM, or a hard disk drive) and/or removable memory (e.g., removable via a universal serial bus connection). Memory 830 may be a non-transitory computer-readable medium. Memory 830 stores information, instructions, and/or software (e.g., one or more software applications) related to the operation of device 800. In some implementations, memory 830 includes one or more memories that are coupled to one or more processors (e.g., processor 820), such as via bus 810.

Input component 840 enables device 800 to receive input, such as user input and/or sensed input. For example, input component 840 may include a touch screen, a keyboard, a keypad, a mouse, a button, a microphone, a switch, a sensor, a global positioning system sensor, an accelerometer, a gyroscope, and/or an actuator. Output component 850 enables device 800 to provide output, such as via a display, a speaker, and/or a light-emitting diode. Communication component 860 enables device 800 to communicate with other devices via a wired connection and/or a wireless connection. For example, communication component 860 may include a receiver, a transmitter, a transceiver, a modem, a network interface card, and/or an antenna.

Device 800 may perform one or more operations or processes described herein. For example, a non-transitory computer-readable medium (e.g., memory 830) may store a set of instructions (e.g., one or more instructions or code) for execution by processor 820. Processor 820 may execute the set of instructions to perform one or more operations or processes described herein. In some implementations, execution of the set of instructions, by one or more processors 820, causes the one or more processors 820 and/or the device 800 to perform one or more operations or processes described herein. In some implementations, hardwired circuitry is used instead of or in combination with the instructions to perform one or more operations or processes described herein. Additionally, or alternatively, processor 820 may be configured to perform one or more operations or processes described herein. Thus, implementations described herein are not limited to any specific combination of hardware circuitry and software.

The number and arrangement of components shown in FIG. 8 are provided as an example. Device 800 may include additional components, fewer components, different components, or differently arranged components than those shown in FIG. 8. Additionally, or alternatively, a set of components (e.g., one or more components) of device 800 may perform one or more functions described as being performed by another set of components of device 800.

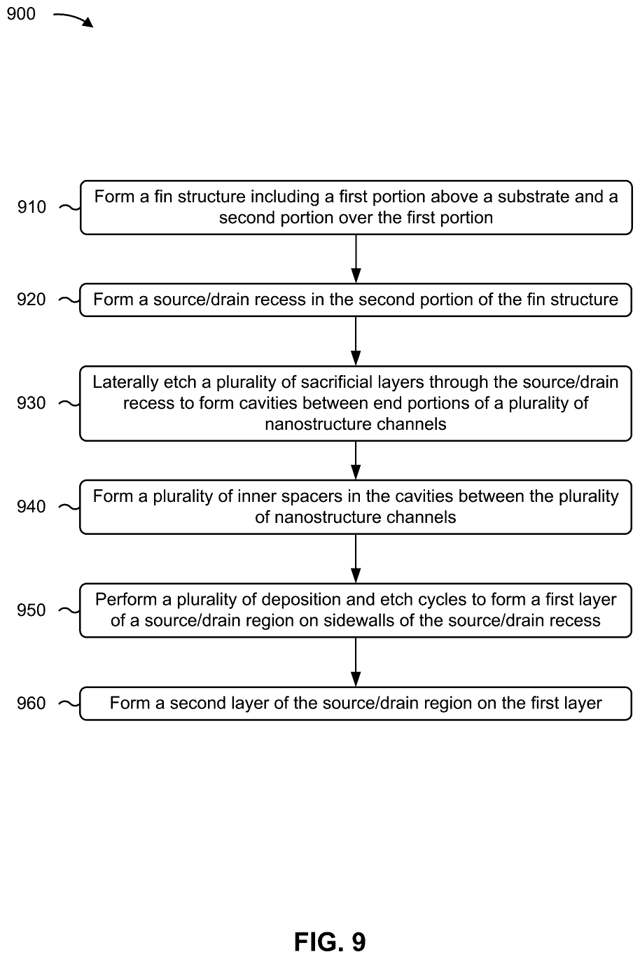

FIG. 9 is a flowchart of an example process 900 associated with forming a semiconductor device. In some implementations, one or more process blocks of FIG. 9 are performed by one or more semiconductor processing tools (e.g., one or more of the semiconductor processing tools 102-112). Additionally, or alternatively, one or more process blocks of FIG. 9 may be performed by one or more components of device 800, such as processor 820, memory 830, input component 840, output component 850, and/or communication component 860.

As shown in FIG. 9, process 900 may include forming a fin structure including a first portion above a substrate and a second portion over the first portion (block 910). For example, one or more of the semiconductor processing tools 102-112 may form a fin structure 204 including a first portion 310 above a substrate 202 and a second portion 308 over the first portion 310, as described above.

As further shown in FIG. 9, process 900 may include forming a source/drain recess in the second portion of the fin structure (block 920). For example, one or more of the semiconductor processing tools 102-112 may form a source/drain recess 320 in the second portion 308 of the fin structure 204, as described above. In some implementations, the second portion 308 includes a plurality of sacrificial layers (e.g., a plurality of first layers 304) and a plurality of nanostructure channels (e.g., a plurality of channels 208) that are arranged in an alternating manner.

As further shown in FIG. 9, process 900 may include laterally etching the plurality of sacrificial layers through the source/drain recess to form cavities between end portions of the plurality of nanostructure channels (block 930). For example, one or more of the semiconductor processing tools 102-112 may laterally etch the plurality of sacrificial layers through the source/drain recess 320 to form cavities 322 between end portions of the plurality of nanostructure channels, as described above.

As further shown in FIG. 9, process 900 may include forming a plurality of inner spacers in the cavities between the plurality of nanostructure channels (block 940). For example, one or more of the semiconductor processing tools 102-112 may form a plurality of inner spacers 324 in the cavities 322 between the plurality of nanostructure channels, as described above.

As further shown in FIG. 9, process 900 may include performing a plurality of deposition and etch cycles to form a first layer of a source/drain region 210 on sidewalls of the source/drain recess (block 950). For example, one or more of the semiconductor processing tools 102-112 may perform a plurality of deposition and etch cycles to form a first layer 504 of a source/drain region 210 on sidewalls 408 of the source/drain recess 320, as described above.

As further shown in FIG. 9, process 900 may include forming a second layer of the source/drain region on the first layer (block 960). For example, one or more of the semiconductor processing tools 102-112 may form a second layer 506 of the source/drain region 210 on the first layer 504, as described above.

Process 900 may include additional implementations, such as any single implementation or any combination of implementations described below and/or in connection with one or more other processes described elsewhere herein.

In a first implementation, performing a deposition and etch cycle of the plurality of deposition and etch cycles includes performing a deposition operation using one or more silicon precursors, and performing, after the deposition operation, an etch operation using hydrochloric acid (HCL). In a second implementation, alone or in combination with the first implementation, the one or more silicon precursors include dichlorosilane (DCS) and silicon tetrahydride (SiH4).

In a third implementation, alone or in combination with one or more of the first and second implementations, a ratio of DCS to SiH4 is in a range of approximately 5:1 to approximately 10:1. In a fourth implementation, alone or in combination with one or more of the first through third implementations, a quantity of the plurality of deposition and etch cycles are in a range of approximately 50 cycles to approximately 60 cycles.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

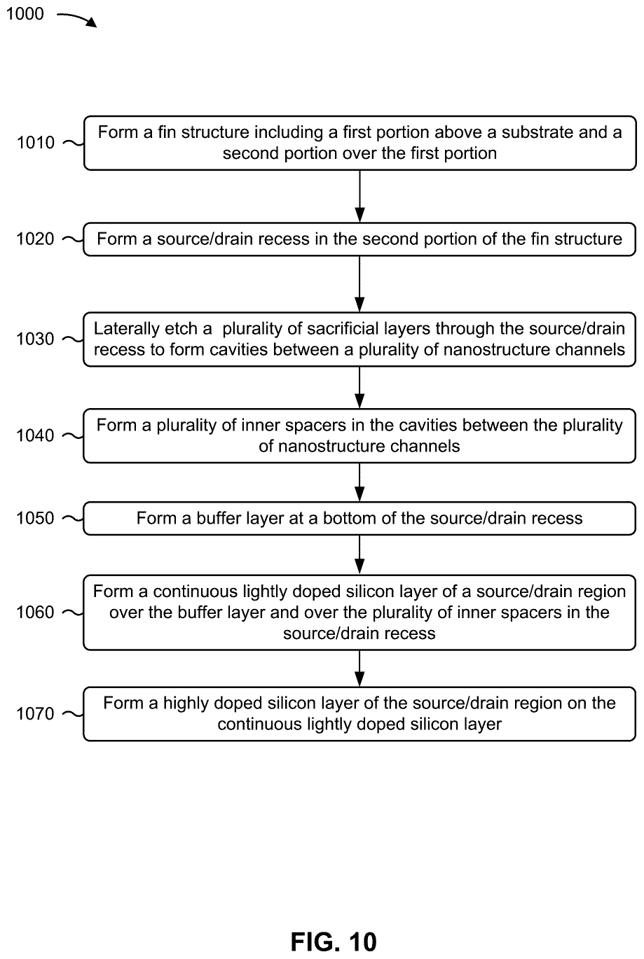

FIG. 10 is a flowchart of an example process 1000 associated with forming a semiconductor device. In some implementations, one or more process blocks of FIG. 10 are performed by one or more of the semiconductor processing tools (e.g., one or more of the semiconductor processing tools 102-112). Additionally, or alternatively, one or more process blocks of FIG. 10 may be performed by one or more components of device 800, such as processor 820, memory 830, input component 840, output component 850, and/or communication component 860.

As shown in FIG. 10, process 1000 may include forming a fin structure including a first portion above a substrate and a second portion over the first portion (block 1010). For example, one or more of the semiconductor processing tools 102-112 may form a fin structure 204 including a first portion 310 above a substrate 202 and a second portion 308 over the first portion 310, as described above.

As further shown in FIG. 10, process 1000 may include forming a source/drain recess in the second portion of the fin structure (block 1020). For example, one or more of the semiconductor processing tools 102-112 may form a source/drain recess 320 in the second portion 308 of the fin structure 204, as described above. In some implementations, the second portion 308 includes a plurality of sacrificial layers (e.g., a plurality of first layers 304) and a plurality of nanostructure channels (e.g., a plurality of channels 208) that are arranged in an alternating manner.

As further shown in FIG. 10, process 1000 may include laterally etching the plurality of sacrificial layers through the source/drain recess to form cavities between the plurality of nanostructure channels (block 1030). For example, one or more of the semiconductor processing tools 102-112 may laterally etch the plurality of sacrificial layers through the source/drain recess 320 to form cavities 322 between the plurality of nanostructure channels, as described above.

As further shown in FIG. 10, process 1000 may include forming a plurality of inner spacers in the cavities between the plurality of nanostructure channels (block 1040). For example, one or more of the semiconductor processing tools 102-112 may form a plurality of inner spacers 324 in the cavities 322 between the plurality of nanostructure channels, as described above.

As further shown in FIG. 10, process 1000 may include forming a buffer layer at a bottom of the source/drain recess (block 1050). For example, one or more of the semiconductor processing tools 102-112 may form a buffer layer 502 at a bottom 406 of the source/drain recess 320, as described above.

As further shown in FIG. 10, process 1000 may include forming a continuous lightly doped silicon layer of a source/drain region over the buffer layer, and over the plurality of inner spacers in the source/drain recess (block 1060). For example, one or more of the semiconductor processing tools 102-112 may form a continuous lightly doped silicon layer (e.g., a first layer 504) of a source/drain region 210 over the buffer layer 502, and over the plurality of inner spacers 324 in the source/drain recess 320, as described above.

As further shown in FIG. 10, process 1000 may include forming a highly doped silicon layer of the source/drain region on the continuous lightly doped silicon layer (block 1070). For example, the one or more of the semiconductor processing tools 102-112 may form a highly doped silicon layer of the source/drain region on the continuous lightly doped silicon layer, as described above.

Process 1000 may include additional implementations, such as any single implementation or any combination of implementations described below and/or in connection with one or more other processes described elsewhere herein.

In a first implementation, the buffer layer 502 includes a (100) grain orientation. In a second implementation, alone or in combination with the first implementation, the buffer layer 502 includes silicon (Si) or silicon germanium (SiGe), the continuous lightly doped silicon layer (e.g., the first layer 504) includes an arsenic-doped silicon (SiAs) or a boron-doped silicon germanium (SiGeB), and the highly doped silicon layer (e.g., the second layer 506) includes a phosphor-doped silicon (SiP) or a boron-doped silicon germanium (SiGeB).

In a third implementation, alone or in combination with one or more of the first and second implementations, the continuous lightly doped silicon layer (e.g., the first layer 504) functions as a shielding layer for the highly doped silicon layer (e.g., the second layer 506). In a fourth implementation, alone or in combination with one or more of the first through third implementations, the process 1000 includes forming a gate structure that includes a plurality of portions that wrap fully around the plurality of nanostructure channels, whereas length of at least a subset of the plurality of inner spacers is greater relative to a thickness of at least a subset of the plurality of portions of the gate structure. In a fifth implementation, alone or in combination with one or more of the first through fourth implementations, process 1000 includes forming a capping layer 508 on the highly doped silicon layer (e.g., the second layer 506), where the capping layer 508 includes a phosphor-doped silicon (SiP) or a boron-doped silicon germanium (SiGeB).

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

In this way, inner spacers (InSPs) and source/drain regions are formed in a manner that provides reduced likelihood of defect formation in a nanostructure transistor. In some implementations, an inner spacer is formed to a length that reduces the likelihood of non-growth in an epitaxial layer of a source/drain region of a nanostructure transistor. This reduces the likelihood that portion of the epitaxial layer become non-merged, which in turn reduces the likelihood of void formation in the source/drain region. Moreover, the epitaxial layer may be formed using a cyclic deposition and etch technique, which enables conformal growth of the epitaxial layer to further reduce the likelihood of void formation and to reduce the likelihood of nodule formation in the source/drain region. The reduction in defects may decrease semiconductor device failure, increase semiconductor device yield, and/or increase semiconductor device performance, among other examples.

As described in greater detail above, some implementations described herein provide a semiconductor device. The semiconductor device includes a plurality of nanostructure channels above a portion of a fin structure. The semiconductor device includes a gate structure, where a plurality of portions of the gate structure wrap around the plurality of nanostructure channels over the portion of the fin structure. The semiconductor device includes a source/drain region adjacent to the plurality of nanostructure channels and adjacent to the portions of the gate structure. The semiconductor device includes a plurality of inner spacers between the plurality of portions of the gate structure and the source/drain region, where a length of at least a subset of the inner spacers is greater relative to a thickness of at least a subset of the plurality of portions of the gate structure, and where the length of at least the subset of the inner spacers is lesser relative to a thickness of the plurality of nanostructure channels.

As described in greater detail above, some implementations described herein provide a method. The method includes forming a fin structure including a first portion above a substrate and a second portion over the first portion. The method includes forming a source/drain recess in the second portion of the fin structure, where the second portion includes a plurality of sacrificial layers and a plurality of nanostructure channels that are arranged in an alternating manner. The method includes laterally etching the plurality of sacrificial layers through the source/drain recess to form cavities between end portions of the plurality of nanostructure channels. The method includes forming a plurality of inner spacers in the cavities between the plurality of nanostructure channels. The method includes performing a plurality of deposition and etch cycles to form a first layer of a source/drain region at a bottom of the source/drain recess and on sidewalls of the source/drain recess. The method includes forming a second layer of the source/drain region on the first layer.

As described in greater detail above, some implementations described herein provide a method. The method includes forming a fin structure that includes a first portion above a substrate and a second portion over the first portion. The method includes forming a source/drain recess in the second portion of the fin structure, where the second portion includes a plurality of sacrificial layers and a plurality of nanostructure channels that are arranged in an alternating manner. The method includes laterally etching the plurality of sacrificial layers through the source/drain recess to form cavities between the plurality of nanostructure channels. The method includes forming a plurality of inner spacers in the cavities between the plurality of nanostructure channels. The method includes forming a buffer layer at a bottom of the source/drain recess. The method includes forming a continuous lightly doped silicon layer of a source/drain region over the buffer layer and over the plurality of inner spacers in the source/drain recess. The method includes forming a highly doped silicon layer of the source/drain region on the continuous lightly doped silicon layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a plurality of nanostructure channels above a portion of a fin structure;
a gate structure,
wherein a plurality of portions of the gate structure wrap around the plurality of nanostructure channels over the portion of the fin structure;
a source/drain region adjacent to the plurality of nanostructure channels and adjacent to the portions of the gate structure; and
a plurality of inner spacers between the plurality of portions of the gate structure and the source/drain region,
wherein a length of at least a subset of the inner spacers is greater relative to a thickness of at least a subset of the plurality of portions of the gate structure, and
wherein the length of at least the subset of the inner spacers is lesser relative to a thickness of the plurality of nanostructure channels.

2. The semiconductor device of claim 1, wherein a ratio of the length of at least the subset of the inner spacers to the thickness of at least the subset of the plurality of portions of the gate structure is in a range of approximately 1.05 to approximately 1.5.

3. The semiconductor device of claim 1, wherein a ratio of the thickness of the plurality of nanostructure channels to the thickness of at least the subset of the plurality of portions of the gate structure is in a range of approximately 1.2 to approximately 1.8.

4. The semiconductor device of claim 1, wherein the plurality of nanostructure channels comprises:
a first nanostructure channel above the portion of the fin structure;
a second nanostructure channel above the first nanostructure channel; and
a third nanostructure channel above the second nanostructure channel,
wherein the source/drain region comprises:
a first layer formed over a buffer layer and over the plurality of inner spacers; and
a second layer formed over the first layer,
wherein the first layer is continuous between the first nanostructure channel and the third nanostructure channel.

5. The semiconductor device of claim 4, wherein a first depth of the first layer relative to a center of the source/drain region, at a height of the third nanostructure channel, is greater relative to a second depth of the first layer relative to the center of the source/drain region at a height of the second nanostructure channel.

6. The semiconductor device of claim 4, wherein the first layer is continuous along opposing sidewalls of the second layer and is continuous along a bottom of the second layer between the opposing sidewalls.

7. The semiconductor device of claim 4, wherein a doping concentration of the second layer is greater relative to a doping concentration of the first layer.

8. The semiconductor device of claim 4, wherein a first width of the first layer, between a nanostructure channel of the plurality of nanostructure channels and the second layer, is greater relative to a second width of the first layer between an inner spacer of the plurality of inner spacers and the second layer.

9. The semiconductor device of claim 8, wherein a ratio of the first width to the second width is in a range of approximately 1.2:1 to approximately 2:1.

10. A semiconductor device, comprising:
a first plurality of nanostructure channels arranged in a direction that is approximately perpendicular to a substrate of a semiconductor device;
a second plurality of nanostructure channels arranged in the direction that is approximately perpendicular to the substrate of the semiconductor device;
a source/drain region laterally between the first plurality of nanostructure channels and the second plurality of nanostructure channels,
a first plurality of inner spacers laterally adjacent to the source/drain region and vertically alternating with ends of the first plurality of nanostructure channels; and
a second plurality of inner spacers laterally adjacent to the source/drain region and vertically alternating with ends of the second plurality of nanostructure channels,
wherein the source/drain region comprises:
a first doped semiconductor layer continuously extending along the ends of the first plurality of nanostructure channels, the first plurality of inner spacers, the ends of the second plurality of nanostructure channels, and the second plurality of inner spacers; and
a second doped semiconductor layer on the first doped semiconductor layer,
wherein a dopant concentration in the second doped semiconductor layer is greater than a dopant concentration in the first doped semiconductor layer.

11. The semiconductor device of claim 10, wherein the first doped semiconductor layer has an approximate U-shaped cross-sectional profile.

12. The semiconductor device of claim 10, wherein a height of a top surface of the second doped semiconductor layer and a height of a top surface of a top-most channel of the first plurality of nanostructure channels are approximately equal.

13. The semiconductor device of claim 10, wherein a height of a top surface of the second doped semiconductor layer is greater than a height of a top surface of a top-most channel of the first plurality of nanostructure channels.

14. The semiconductor device of claim 10, wherein a height of a top surface of the second doped semiconductor layer is less than a height of a top surface of a top-most channel of the first plurality of nanostructure channels.

15. The semiconductor device of claim 10, wherein the first doped semiconductor layer and the second doped semiconductor layer comprise a same semiconductor material;
wherein the first doped semiconductor layer comprises a first n-type dopant;
wherein the second doped semiconductor comprises a second n-type dopant; and
wherein the first n-type dopant and the second n-type dopant are different n-type dopants.

16. The semiconductor device of claim 10, wherein the first doped semiconductor layer and the second doped semiconductor layer comprise a same semiconductor material; and
wherein the first doped semiconductor layer and the second doped semiconductor layer comprise a same p-type dopant.

17. A semiconductor device, comprising:
a plurality of nanostructure channels arranged in a direction that is approximately perpendicular to a substrate of a semiconductor device;
a source/drain region laterally adjacent to the plurality of nanostructure channels; and
a plurality of inner spacers laterally adjacent to the source/drain region and vertically alternating with ends of the plurality of nanostructure channels,
wherein the source/drain region comprises:
a semiconductor buffer layer located at a lower vertical position in the semiconductor device than a top surface of a bottom-most nanostructure channel of the plurality of nanostructure channels;
a first doped semiconductor layer continuously extending along the ends of the plurality of nanostructure channels; and
a second doped semiconductor layer on the first doped semiconductor layer,
wherein a dopant concentration in the second doped semiconductor layer and a dopant concentration in the first doped semiconductor layer are different dopant concentrations.

18. The semiconductor device of claim 17, wherein the semiconductor buffer layer includes a (100) grain orientation.

19. The semiconductor device of claim 17, wherein the semiconductor buffer layer comprises silicon (Si) or silicon germanium (SiGe);
wherein the first doped semiconductor layer comprises an arsenic-doped silicon (SiAs) or a boron-doped silicon germanium (SiGe:B); and
wherein the second doped semiconductor layer comprises a phosphor-doped silicon (SiP) or a boron-doped silicon germanium (SiGe:B).

20. The semiconductor device of claim 17, wherein the source/drain region further comprises:
a semiconductor capping layer on the second doped semiconductor layer,
wherein the semiconductor capping layer comprises a phosphor-doped silicon (SiP) or a boron-doped silicon germanium (SiGe:B).
